(19) United States
(12) Patent Application Publication
(10) Pub. No.: US 2025/0185485 A1
(43) Pub. Date: Jun. 5, 2025

(54) SUBPIXEL DESIGNS FOR DISPLAY DEVICE WITH UNDER DISPLAY CAMERA

(71) Applicant: Microsoft Technology Licensing, LLC, Redmond, WA (US)

(72) Inventor: Scott PIECUCH, Seattle, WA (US)

(21) Appl. No.: 18/524,362

(22) Filed: Nov. 30, 2023

(51) Int. Cl. H10K 59/65; H10K 59/35; H10K 71/16; H10K 71/60

(52) U.S. Cl. CPC H10K 59/65; H10K 59/353; H10K 71/166; H10K 71/60

(57) ABSTRACT

Display devices, display panels, and methods for manufacture thereof described herein provide sub-pixel designs for display devices with under display cameras. In an aspect, a display panel comprising a display portion is provided. The display portion comprises a first sub-pixel and a second sub-pixel. The first and second sub-pixels include respective static corners at a same position relative to a respective sub-pixel center and respective dynamic corners. The position of each dynamic corner is located such that shapes of the first and second sub-pixels are different. In another aspect, a method for manufacturing a semiconductor component is provided. An organic material is deposited on first and second anodes utilizing a mask arranged over semiconductor material. The mask comprises first and second sub-pixel regions, each of which have a respective static corner and a respective dynamic corner such that shapes of the first and second sub-pixel regions are different.

### BACKGROUND

An under display camera (UDC) is a camera positioned behind or otherwise beneath a display panel. The UDC captures incident light that passes through the display panel. The display panel includes structures (e.g., pixel areas, thin-film transistors, traces, etc.) for which at least part of those structures are positioned between a surface of the display panel and the UDC.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Embodiments are described herein for sub-pixel designs for display devices with under display cameras. A display panel is provided. The display panel comprises a first display portion comprising a first sub-pixel and a second sub-pixel. Each of the first and second sub-pixels include a respective first static corner at a same position relative to a respective sub-pixel center and a respective first dynamic corner. The position of each first dynamic corner is located such that the shape of the first sub-pixel is different from the shape of the second sub-pixel.

In a further aspect, the first display portion comprises a pixel comprising the first sub-pixel and a third sub-pixel that includes a second static corner and a second dynamic corner. The first sub-pixel is adjacent to the third sub-pixel. The position of the first dynamic corner of the first sub-pixel is located to decrease an interior angle relative to the interior angle of the first dynamic corner in a regular polygon configuration of the first sub-pixel. The position of the second dynamic corner of the third sub-pixel is located to increase an interior angle of the second dynamic corner in a regular polygon configuration of the third sub-pixel.

In a further aspect, the position of each first dynamic corner is located to decrease an interior angle relative to the interior angle of the respective first dynamic corner in a regular polygon configuration of the respective sub-pixel.

In a further aspect, the display device comprises a camera arranged beneath the first display portion of the display panel and is configured to capture images formed of incident light having passed through the display panel to the camera.

In a further aspect, the display device comprises an image processing system configured to receive an image captured by the camera and utilize a machine learning (ML) model to filter a visual artifact from the image to generate a processed image.

In another aspect, a method for manufacturing a semiconductor component is provided. A semiconductor material having a major surface and comprising first and second anodes is provided. An organic material is deposited on the first and second anodes utilizing a mask arranged over the semiconductor material. The mask comprises a first sub-pixel region and a second sub-pixel region. Each of the first and second sub-pixel regions respectively comprise a respective first static corner at a same position relative to a respective sub-pixel center and a respective first dynamic corner, wherein the position of each first dynamic corner is located such that a shape of the first sub-pixel region is different from the shape of the second sub-pixel region. Cathodes are applied to each of the first and second sub-pixel regions of the deposited organic material.

In a further aspect, depositing the organic material comprises arranging a first sub-mask of the mask over the semiconductor material, depositing a first color of organic material on the first anode utilizing the first sub-mask, arranging a second sub-mask of the mask over the semiconductor material, and depositing a second color of organic material on the second anode utilizing the second sub-mask. The first sub-mask comprises the first sub-pixel region. The second sub-mask comprises the second sub-pixel region.

### BRIEF DESCRIPTION OF THE DRAWINGS/FIGURES

The accompanying drawings, which are incorporated herein and form a part of the specification, illustrate embodiments and, together with the description, further serve to explain the principles of the embodiments and to enable a person skilled in the pertinent art to make and use the embodiments.

FIG. 1A shows a block diagram of an implementation of a system that includes an under display camera.

FIG. 1B shows an example diagram of a point spread function corresponding to the system of FIG. 1A.

FIG. 2 shows a block diagram of a system that includes a user device with a display portion comprising modified sub-pixels, according to an example embodiment.

FIG. 3 shows a block diagram of the user device of FIG. 2, according to an example embodiment.

FIG. 4A shows a block diagram of a display panel that comprises modified sub-pixels, according to an example embodiment.

FIG. 4B shows a block diagram of pixels of the display panel of FIG. 4A, according to an example embodiment.

FIG. 5 shows a block diagram of a pixel pattern, according to an example embodiment.

FIG. 6A shows a block diagram of a portion of the pixel pattern of FIG. 5, according to an example embodiment.

FIG. 6B shows a block diagram of a portion of the pixel pattern of FIG. 5, according to an example embodiment.

FIG. 7A shows a block diagram of a system that includes a display panel with modified sub-pixels, according to an example embodiment.

FIG. 7B shows a diagram of a point spread function corresponding to the system of FIG. 7A, according to an example embodiment.

FIG. 8 shows a block diagram of a display device comprising modified sub-pixels, according to an example embodiment.

FIGS. 9A-9H show a manufacturing process of the display panel of FIG. 8, according to an example embodiment.

FIG. 10 shows a flowchart of a process for manufacturing a semiconductor device, according to an example embodiment.

FIG. 11 shows a flowchart of a process for depositing organic material, according to an example embodiment.

FIG. 12A shows a block diagram of a mask, in accordance with an example embodiment.

FIG. 12B shows a block diagram of a mask, according to an example embodiment.

FIG. 12C shows a block diagram of a sub-mask, according to an example embodiment.

FIG. 13 shows a block diagram of a system for capturing and processing images, according to an example embodiment.

FIG. 14 shows a flowchart of a process for processing an image, according to an example embodiment.

FIG. 15A shows a block diagram of a pixel pattern, according to another example embodiment.

FIG. 15B shows a block diagram of a pixel pattern, according to another example embodiment.

FIG. 15C shows a block diagram of a pixel pattern, according to another example embodiment.

FIG. 16 shows a computing device that includes a display panel with modified sub-pixels, according to an example embodiment.

FIG. 17 shows a block diagram of an example computing system in which embodiments may be implemented.

The subject matter of the present application will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

### I. Introduction

The following detailed description discloses numerous example embodiments. The scope of the present patent application is not limited to the disclosed embodiments, but also encompasses combinations of the disclosed embodiments, as well as modifications to the disclosed embodiments. It is noted that any section/subsection headings provided herein are not intended to be limiting. Embodiments are described throughout this document, and any type of embodiment may be included under any section/subsection. Furthermore, embodiments disclosed in any section/subsection may be combined with any other embodiments described in the same section/subsection and/or a different section/subsection in any manner.

### II. Example Embodiments Display Devices and Sub-Pixel Designs

Embodiments described herein provide for sub-pixel designs for display devices. In particular, several example embodiments of sub-pixel designs are described herein that reduce visual artifacts in images captured by under display cameras (UDCs) and/or increase the sub-pixel area of the display area near the under display camera. In displays with a UDC, pixels (and sub-pixels of the pixel) and other structures (e.g., thin film transistors (TFT), traces, etc.) of the display may interfere with light that passes through the display to the UDC. For instance, the structures may block and/or scatter a portion of the light that passes through the display panel and is captured by the UDC. Scattered light can cause visual artifacts to appear in images captured by the UDC (e.g., color fringing, trails of light, and/or other visual artifacts). Depending on the implementation, the visual artifacts may be difficult to remove or otherwise correct.

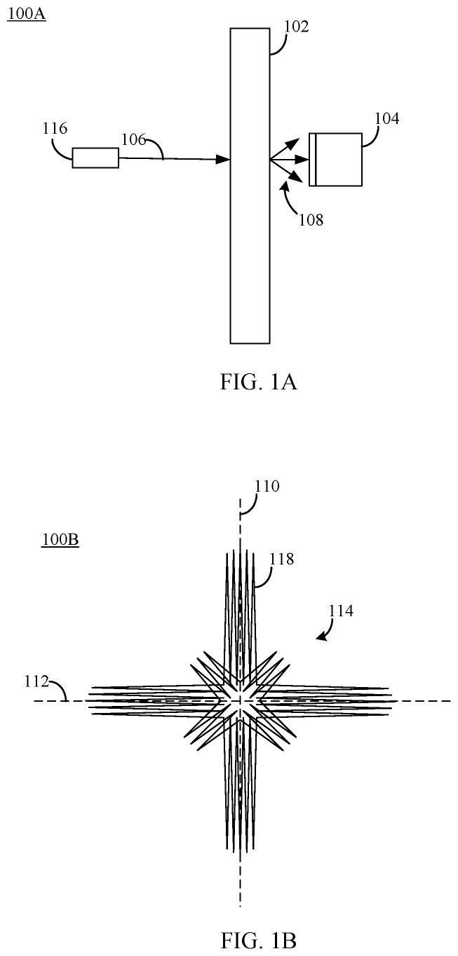

To better illustrate the scattering of light passing through a display, FIGS. 1A and 1B will now be described. FIG. 1A shows a block diagram of an implementation of a system 100A that includes an under display camera. FIG. 1B shows an example diagram 100B of a point spread function corresponding to system 100A of FIG. 1A. System 100A comprises a display panel 102, a camera 104, and a point source 116. In an embodiment, display panel 102 and camera 104 are incorporated in a single device (e.g., a computing device or a user device). Display 102 is a semi-transparent display (e.g., a semi-transparent organic light emitting diode (OLED) display). Camera 104 is an under display camera (UDC). In accordance with an embodiment, pixels and/or stack layers are removed around the camera area of display 102 to improve camera 104's capture of incident light. Point source 116 is an example source of light or other object that projects a point of light. In embodiments, camera 104 captures light from point source 116 that passes through display 102.

For example, as shown in FIG. 1A, point source 116 projects light 106. Light 106 passes through display 102. The pixels and other structures within display 102 (not shown in FIG. 1A) interfere with light 106 and cause it to scatter as scattered light 108. In some cases, light 106 scatters as scattered light 108 (e.g., approximately) perpendicular to edges of pixels (or sub pixels) and other structures within display 102. The repeated periodic pattern of pixels in display 102 causes scattered light 108 to cause visual artifacts in images formed from incident light captured by camera 104.

With respect to point source 116 and FIG. 1A, the scattered light captured by camera 104 is represented as point spread function 114 (“PSF 114” herein) in FIG. 1B. PSF 114 is illustrated on a major vertical axis 110 and a major horizontal axis 112. The scattering of light 206 causes high energy lines (such as high energy line 118), which cause visual artifacts in images captured by camera 104.

Embodiments of the present disclosure provide sub-pixel designs that reduce the high energy lines in the point spread function of light passing through the display, thereby reducing visual artifacts that appear in the images taken by a UDC. For instance, a display panel comprising a display portion is provided in an example embodiment. The display portion comprises a first sub-pixel and a second sub-pixel. Each of the first and second sub-pixels include a respective first static corner and a respective first dynamic corner. A “static corner” is a corner that is located in the same position with respect to a sub-pixel center as the corner would be in a regular configuration of the sub-pixel. A “dynamic corner” is a corner that is located in a different position with respect to a sub-pixel center as the corner would be in a regular configuration of the sub-pixel. In this context, a “regular configuration” of a sub-pixel is a configuration of the sub-pixel where positions of corners follow a standard or periodic pattern. For example, in an embodiment where a regular configuration of a sub-pixel is a regular polygon (i.e., an equiangular and equilateral polygon), the static corners of the sub-pixel are in the same position as respective corners of the regular polygon and the dynamic corners are in different positions from their respective corners of the regular polygon. In another example wherein the regular configuration of sub-pixels of a same type is a irregular polygon (e.g., a trapezoid, a star, a fan, a semi-circle, etc.), the static corners of each sub-pixel of the same type are in the same position as respective corners of the irregular polygon and the dynamic corners of sub-pixels of the same type are in different positions than respective corners of the irregular polygon. In other words, static corners of each sub-pixel of the same type are in the same position as respective corners of an imaginary representation of the irregular polygon without dynamic corners and the dynamic corners of those sub-pixels are in different positions than respective corners of the imaginary representation of the irregular polygon.

Respective static corners for each sub-pixel of the same type are located at a same position relative to a respective sub-pixel center. For instance, in a non-limiting example suppose two pixels each comprise a red hexagon shaped sub-pixel, a green hexagon shaped sub-pixel, and a blue hexagon shaped sub-pixel. Further suppose respective centers of each sub-pixel of the same type is located in a same position with respect to a center of the respective pixel (i.e., the centers of red sub-pixels are in a first position with respect to a center of the respective pixel, the centers of green sub-pixels are in a second position with respect to the center of the respective pixel, and the centers of blue sub-pixels are in a third position with respect to the center of the respective pixel). In this example, static corners of each red sub-pixel are in the same position with respect to a center of the respective pixel, static corners of each green sub-pixel are in the same position with respect to a center of the respective pixel, and static corners of each blue sub-pixel are in the same position with respect to a center of the respective pixel.

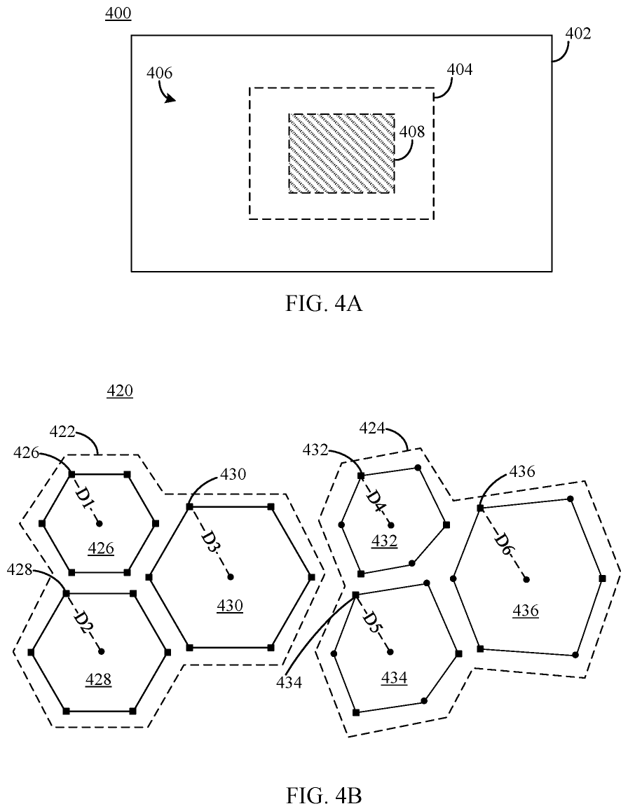

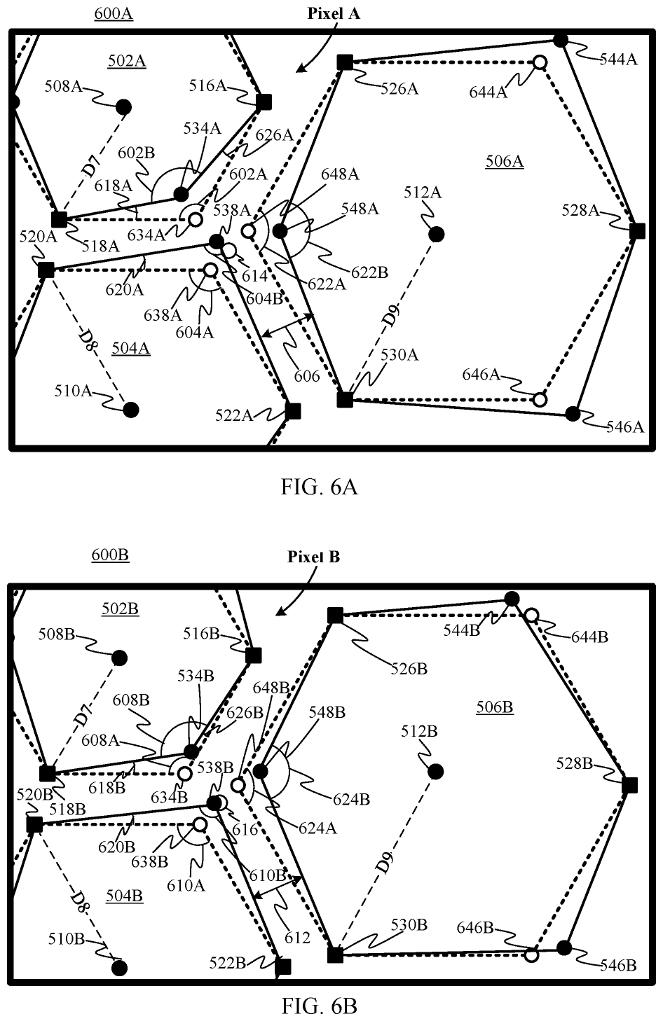

The position of each dynamic corner is located such that a shape of the first sub-pixel is different from the shape of the second sub-pixel. For instance, in the non-limiting example, dynamic corners of the red sub-pixels are located such that shapes of the two red sub-pixels are different, dynamic corners of the green sub-pixels are located such that shapes of the two green sub-pixels are different, and dynamic corners of the blue sub-pixels are located such that shapes of the two blue sub-pixels are different. Additional details regarding the location of positions of dynamic and static corners are further described with respect to FIGS. 4B, 5, 6A, 6B, and 15A-15C, as well as elsewhere herein. By locating positions of dynamic corners for sub-pixels in a manner such that the sub-pixels are different shapes in this way, the periodicity of angles of edges of sub-pixels is disrupted. The irregularity of angles causes the PSF of light passing through the display to have lower energy lines, thereby reducing or removing visual artifacts that appear in images taken by a UDC. Further details regarding the impact to the PSF are discussed with respect to FIGS. 6A and 6B, as well as elsewhere herein.

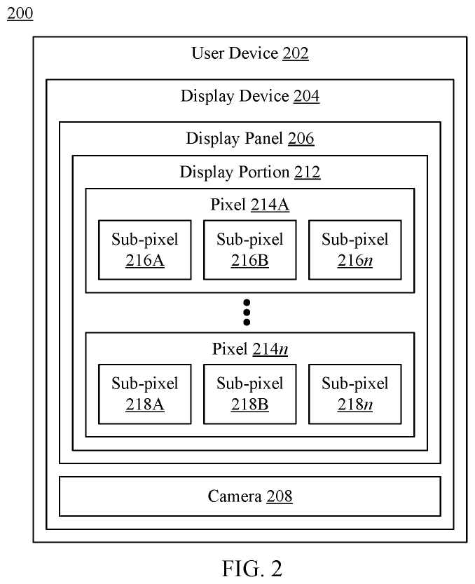

To better understand embodiments of display panels and display devices that implement the above-described sub-pixels with dynamic and static corners, FIG. 2 will now be described. FIG. 2 shows a block diagram of a system 200 that includes a user device with a display portion comprising modified sub-pixels, according to an example embodiment. As shown in FIG. 2, user device 102 includes a display device 204, which includes a display panel 206, and a camera 208. In accordance with an embodiment, display panel 206 is an OLED display, however, embodiments described herein are not so limited). Display panel 206 comprises a display portion 212, which comprises a plurality of pixels 214A-214n (“pixels 214A-214n” herein). Each pixel of pixels 214A-214n comprises one or more sub-pixels. For instance, as shown in FIG. 2, pixel 214A includes sub-pixels 216A-216n and pixel 214n includes sub-pixels 218A-216n. User device 202 is described as follows.

User device 202 may be any type of stationary or mobile electronic device that includes a display (touch sensitive or not touch sensitive), including, but not limited to, a desktop computer, a server, a mobile or handheld device (e.g., a tablet, a personal data assistant (PDA), a cell phone, a smartphone, a laptop, a netbook, etc.), a wearable computing device (e.g., a smart watch, a head-mounted device (e.g., smart glasses, a virtual reality headset, etc.), a display in an automobile (e.g., a dashboard, a navigation panel, an infotainment panel, etc.), a portable media player, a stationary or handheld gaming console, a personal navigation assistant, a camera, a television, an Internet-of-Things (IoT) device, or other type of electronic device.

Display device 204 is configured to enable the display of content by user device 202 on display panel 206 and the capture of incident light by camera 208 to form images. In addition to display panel 206 and camera 208, display device includes any additional hardware and software and/or firmware used to enable display device 104 to display content and capture incident light. For example, display device 104 may include a graphics subsystem, one or more processors, and/or one or more memories (physical hardware) not shown in FIG. 2 for illustrative brevity.

Display panel 206 displays visible content to users. In particular, colored light is emitted from display panel 206 as content to be viewed by users. Display panel 206 generates light using pixels 214A-214n. Pixels 214A-214n in accordance with an embodiment are OLED pixels. As shown in FIG. 2, pixel 214A includes sub-pixels 216A-216n and pixel 214n includes sub-pixels 218A-218n. Each sub-pixel of pixels 214A-214n is configured to emit light of a particular color. In some embodiments, each sub-pixel of a pixel emits a different color light. For example, in an embodiment of display panel 206, sub-pixels 216A and 218A emit red light, sub-pixels 216B and 218B emit green light, and sub-pixels 216n and 218n emit blue light. In some embodiments, two or more sub-pixels of a pixel emit the same color light (e.g., in an example embodiment of a red-green-blue pixel with five sub-pixels two sub-pixels emit green light and two sub-pixels emit red light). In embodiments, the brightness of sub-pixels 216A-216n and 218A-218n (as well as other sub-pixels of display panel 206 not shown in FIG. 2 for brevity) are controlled separately. The respective brightness levels of the colors may be determined as a function of the image to be displayed. The brightness of each light source may depend on the intensities of respective colors present in the image to be displayed.

Camera 208 is an under display camera and is configured to capture incident light that passes through display panel 206 (e.g., through display portion 212). Examples of camera 208 include, but are not limited to, a complementary metal-oxide semiconductor (CMOS) sensor, a charge-coupled device (CCD) sensor, other type of pixel arrays for capturing colored pixel information (e.g., red, green, and blue (RGB) pixel information, red, green, blue, and white (RGBW) pixel information, red, green, blue, and clear (RGBC) pixel information, etc.).

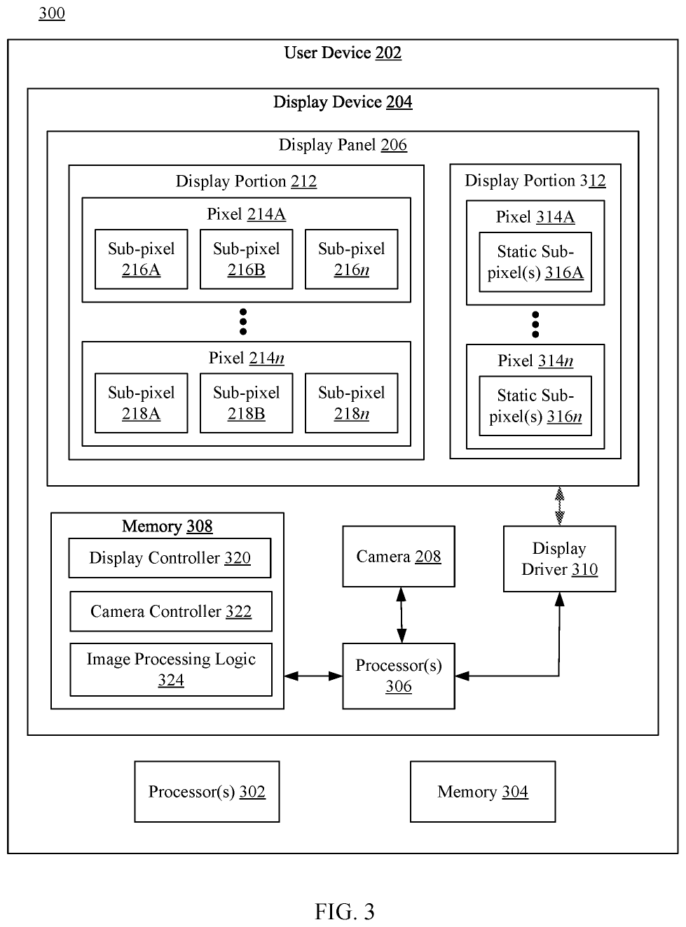

As shown in FIG. 2, display panel 206 comprises display portion 212. Display portion 212 corresponds to at least a portion of the display area of display panel 206. For instance, display portion 212 comprises pixels 214A-214n. In some embodiments, and as discussed further with respect to FIGS. 3 and 4A (as well as elsewhere herein), display panels may comprise multiple display portions. In accordance with an embodiment, camera 208 is located behind or otherwise beneath display portion 212. To facilitate camera 208 to capture light, pixels 214A-214n of display portion 212 are arranged in a manner that allows light to pass through at least a portion of display portion 212 and to be captured by camera 208 (e.g., as incident light). In embodiments, positions of corners of sub-pixels 216A-216n and 218A-218n are located in a manner that reduces visual artifacts that appear in images generated by camera 208 from captured light. Additional details regarding the location of the positions of corners of sub-pixels are further discussed with respect to FIGS. 4B, 5, 6A, 6B, and 15A-15C, as well as elsewhere herein. In embodiments, sub-pixels 216A-216n and 218A-218n may be referred to as “modified sub-pixels.”

User device 202, display device 204, and display panel 206 may be configured in various ways to perform their functions. For instance, FIG. 3 shows a block diagram of a system 300 that includes user device 202 of FIG. 2, according to an example embodiment. As shown in FIG. 3, user device 202 includes display device 204 (as described with respect to FIG. 2), one or more processors 302 (“processor 302” hereinafter), and one or more memories 304 (“memory 304” hereinafter). Display device 204 includes display panel 206 and camera 208 as described with respect to FIG. 2, as well as one or more processors 306 (“processor 306” hereinafter), one or more memories 308 (“memory 308” hereinafter), and a display driver 310. Memory 308 stores a display controller 320, a camera controller 322, and image processing logic 324. System 300 of FIG. 3 is described in further detail as follows.

Display device 204 is communicatively coupled to processor 302 and memory 304 to support the display of video or other images by display panel 206 and the capture of incident light and generation of images by camera 208. For example, processor 302 may provide data indicative of each image frame of video/images to display device 204. The data may be generated by processor 302, another component of user device 202, and/or obtained by processor 302 (e.g., from memory 304, from an image source external to user device 202 not shown in FIG. 3 (e.g., a device and/or service executing on a device communicatively coupled to user device 202 over a wired and/or wireless network to provide image and/or video data to user device 102 (e.g., a streaming media player, a DVD player, a Blu-Ray player, a streaming service hosted on a server, an external memory that stores image and/or video data, etc.)), from another component of user device 202, and/or the like). Examples of processor 302 include, but are not limited to, a central processing unit (CPU), a graphics-processing unit (GPU), and/or another processor or processing unit.

Processor 306 may be a CPU, a GPU, and/or any other type of processor or processing unit configured for graphics-related functionality, display-related functionality, and/or camera-related functionality. Some embodiments of processor 306 include multiple processors (e.g., a first processor or processor core configured for functionality related to display panel 206 and a second processor or processor core configured for functionality related to camera 208). Some of the components of display device 204 may be integrated. For example, processor 306, memory 308, and/or display driver 310 may be integrated as a system-on-a chip (SoC) or application-specific integrated circuit (ASIC). Display device 204 may include additional, fewer, or alternative components than those shown in FIG. 3. For example, display device 204 in accordance with an embodiment may not include a dedicated processor, and instead rely on processor 302. In accordance with another embodiment, display device 204 does not include memory 308, and instead uses memory 304 to support display-related and camera-related processing. In embodiments, instructions implemented by, and data generated or used by, processor 306 are stored in memory 304, memory 308, or a combination of memory 304 and memory 308.

Display panel 206 comprises display portion 212 (comprising pixels 214A-214n, which respectively comprise sub-pixels 216A-216n and sub-pixels 218A-218n) as described with respect to FIG. 2. As shown in FIG. 3, display panel 206 also comprises display portion 312. Display portion 312 comprises pixels 314A-314n.

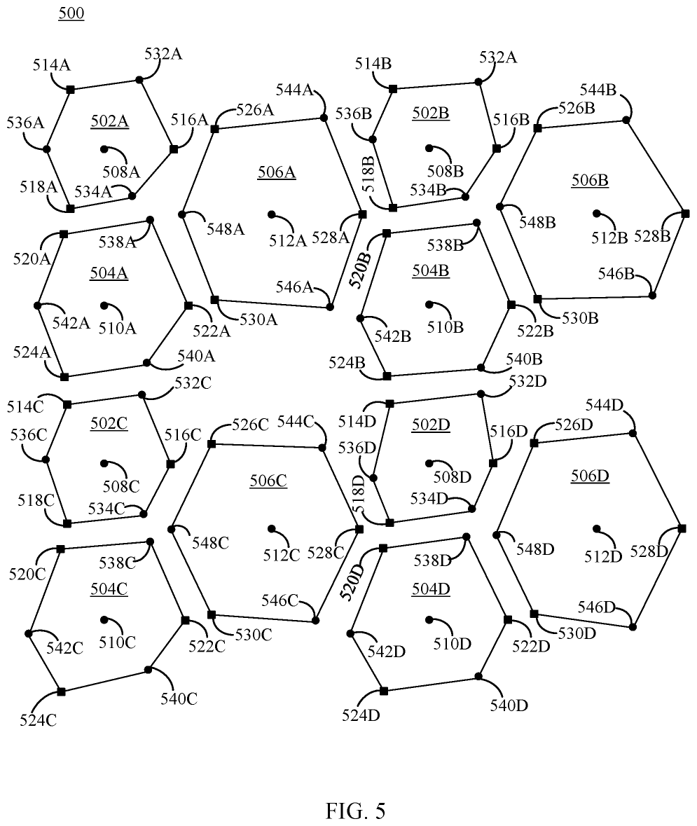

As described with respect to FIG. 2 (and elsewhere herein), to facilitate camera 208 to capture light, pixels 214A-214n of display portion 212 are arranged in a manner that allows light to pass through at least a portion of display portion 212 and to be captured by camera 208. Furthermore, in embodiments, positions of corners of sub-pixels 216A-216n and 218A-218n are located in a manner that reduces visual artifacts that appear in images generated by camera 208 from captured light (additional details of which will be described elsewhere herein). The positions of corners of sub-pixels that are located in this manner are also referred to as “dynamic corners” herein. In accordance with one or more embodiments, sub-pixels of display portion include both dynamic corners and “static corners.” Static corners are corners that are at the same position relative to a respective sub-pixel center for two or more sub-pixels of different pixels. In this context, the two sub-pixels are in the same relative position and/or are the same sub-pixel type in their respective pixels. For instance, suppose pixel 214A and pixel 214B are RGB pixels with one red sub-pixel (sub-pixel 216A and sub-pixel 218A, respectively), one green sub-pixel (sub-pixel 216B and sub-pixel 218B, respectively), and one blue sub-pixel (sub-pixel 216n and sub-pixel 218n, respectively). In this context, static corners of sub-pixels 216A and 218A are in the same position relative to a respective sub-pixel center, static corners of sub-pixels 216B and 218B are in the same position relative to a respective sub-pixel center, and static corners of sub-pixels 216n and 218n are in the same position relative to a respective sub-pixel center. Additional details regarding the positioning of dynamic and static corners of sub-pixels of different pixels are described with respect to FIGS. 4, 5A, and 5B, as well as elsewhere herein.

In some embodiments, other pixels of other display portions of display panel 206 may be configured in the same or a different manner than the display portion camera 208 is positioned behind (or beneath) (e.g., display portion 212). For instance, pixels (and sub-pixels) of display portion 312 in accordance with an embodiment are configured in a similar manner as the pixels of display portion 212 (i.e., sub-pixels of pixels 314A-314n include both static and dynamic corners). Alternatively, and as shown in FIG. 3, pixels of display portion 312 in accordance with an embodiment are configured in a different manner than pixels of display portion 212. For instance, as shown in FIG. 3, pixels 314A-314n comprise one or more respective static sub-pixels 316A-316n. Static sub-pixels 316A-316n include no dynamic corners (i.e., only static corners). For instance, for each pixel, each corner of a sub-pixel of the same type and/or position with respect to the respective pixel's center is in the same position relative to the respective sub-pixel's center. By having a portion of the display area comprise “static” pixels, the complexity of the manufacturing of display panel 206 is reduced (e.g., because only the portion of the display panel corresponding to the under display camera has pixels with irregular or otherwise modified shapes, whereas pixels in the remaining portion of the display panel are (relatively) uniform).

Processor 306 in accordance with an embodiment individually controls each sub-pixel in display panel 206 to determine which sub-pixels for each pixel are illuminated and the intensity (e.g., the brightness) of each sub-pixel. In this example, processor 306 is configured to execute code of display controller 320 and/or display driver 310 to control display panel 206. Alternatively, display driver 310 is implemented in the form of hardware (e.g., electrical circuits including one or more processors, logic gates, and/or transistors) that may or may not execute one or both of firmware and software.

As described with respect to FIG. 2, camera 208 is configured to capture images formed of incident light that passes through display panel 2006 to camera 208. In accordance with an embodiment, processor 306 controls camera 208 to capture images. In this example, processor 306 is configured to execute code of camera controller 322 to control camera 208. For instance, processor 306 may execute code to adjust one or more settings of camera 208 (e.g., a focus setting, a shutter speed setting, a light sensitivity setting, an exposure value setting, a white balance setting, etc.), capture a still image with camera 208, capture video with camera 208, capture multiple still images (e.g., a series of still images) with camera 208, and/or perform any other function associated with camera 208 and/or otherwise related to the capture of images.

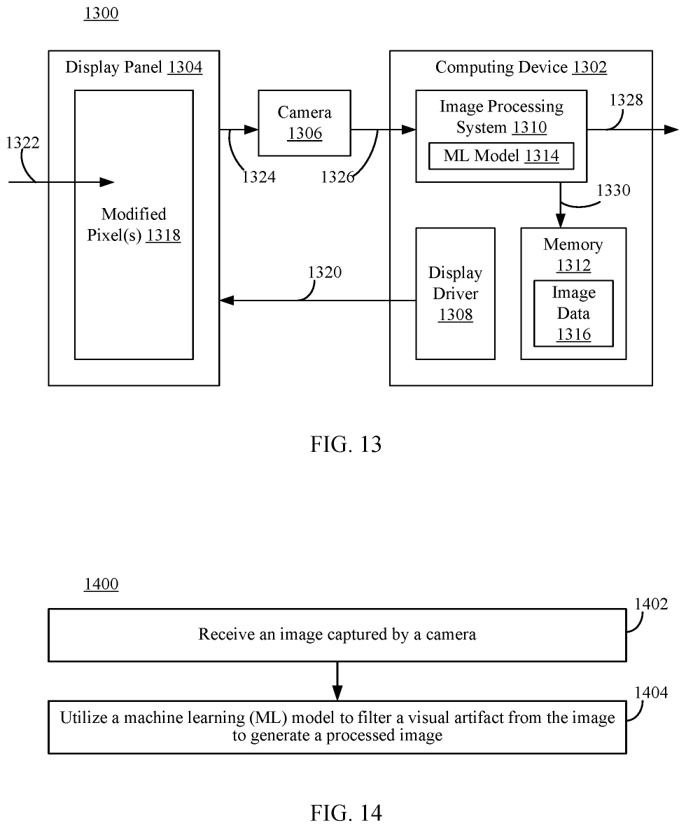

Processor 306 in accordance with an embodiment is further configured to process images captured with camera 208. For example, processor 306 executes code of image processing logic 324 to perform one or more functions related to the processing of images captured with camera 208. Processor 306 may execute code of image processing logic 324 to convert a file type of an image, remove a visual artifact from an image, adjust a resolution of an image, compress an image, modify an image, apply a visual filter to an image, and/or any other type of function related to processing of images captured by camera 208. As a non-limiting example, and as further discussed with respect to FIGS. 13 and 14 (as well as elsewhere herein), processor 306 executes code to utilize a machine learning (ML) model to filter a visual artifact from an image captured by camera 208.

As discussed with respect to FIG. 3, embodiments of display panel 206 may include multiple display portions. Furthermore, pixels of different display portions within a display panel may be configured in different ways, in embodiments. For example, FIG. 4A shows a block diagram 400 of a display panel 402 that comprises modified sub-pixels, according to an example embodiment. FIG. 4B shows a block diagram 420 of pixels of the display panel of FIG. 4A, according to an example embodiment. Display panel 402 is a further example of display panel 206, as described with respect to FIGS. 2 and 3. Further structural and operational embodiments will be apparent to persons skilled in the relevant art(s) based on the following description of FIGS. 4A and 4B.

As shown in FIG. 4A, display panel 402 comprises a first display portion 404 and a second display portion 406. First display portion 404 is a further example of display portion 212 (as described with respect to FIGS. 2 and 3) and second display portion 406 is a further example of display portion 312 (as described with respect to FIG. 3). As shown in FIG. 4A, display portion 406 surrounds edges of display portion 404; however, embodiments described herein are not so limited. For example, in other embodiments, display portions 404 and 406 may be adjacent display portions (e.g., halves of the display area of display panel 402), display portion 404 may be arranged in an edge or corner of display panel 402, display portion 404 may surround edges of display portion 406, and/or display portions 404 and 406 may be arranged in any other manner across the display area of display panel 402.

As also shown in FIG. 4A, display portion 404 comprises a sub-portion 408. Sub-portion 408 represents the position of an under display camera (e.g., camera 208) located behind (or otherwise beneath) display portion 404. As shown in FIG. 4A, display portion 404 is larger than sub-portion 408, thus enabling the camera to capture incident light that passes through display portion 404 at an angle relative to the position of the camera (e.g., at a field of view wider than the width of the camera lens).

Display panel 402, display portions 404 and 406, and sub-portion 408 are shown as rectangular shaped display areas in FIG. 4A. However, display panel 402, display portion 404, display portion 406, and/or sub-portion 408 may be in any type of shape suitable for a display panel and/or display area, including, but not limited to other quadrilateral shapes (e.g., squares, trapezoids, etc.), circular shapes, other polygon shapes, quasi-polygon shapes (e.g., polygons with filleted corners, polygons with chamfered corners, etc.). For instance, display portion 404 in accordance with an embodiment is shaped and sized based on the field of view of the under display camera (e.g., as an oval or circle shape) such that display portion 404 covers the field of view of the under display camera and display portion 406 does not cover the field of view of the under display camera (or covers a minimal or otherwise reduced amount of the field of view of the under display camera). Furthermore, display panel 402 in FIG. 4A has a two-dimensional (e.g., a “flat panel”) display area. In an alternative embodiment, display panel 402 includes one or more beveled edges. In another alternative embodiment, display panel 402 is a curved display (e.g., a display with a concave or convex viewing surface).

In embodiments, pixels of display areas 404 and 406 may be configured differently. For instance, in accordance with an embodiment, sub-pixels of pixels of display area 404 include “dynamic” and “static” corners while sub-pixels of pixels of display area 406 include no dynamic corners. As an example, FIG. 4B comprises an example pixel 422 of display portion 406 and an example pixel 424 of display portion 404. Pixel 422 includes sub-pixels 426, 428, and 430 and pixel 424 includes sub-pixels 432, 434, and 436. Static corners of sub-pixels 426-436 (including representative static corners 426-436) are represented with squares and dynamic corners of sub-pixels 432-436 are represented with circles. Pixels 422 and 424 are described as follows.

Pixel 422 is a further example of pixel 314A and/or pixel 314n of FIG. 3. Pixel 422 is also referred to as a “static” pixel. In this context, a static pixel is a pixel with sub-pixels that have no dynamic corners (i.e., only static corners). As shown in FIG. 4B, each corner of sub-pixels 426-430 is a static corner (represented with a square). As a non-limiting example, suppose display portion 406 of FIG. 4A comprises multiple pixels that are the same pixel as pixel 422. In this context, each of these pixels comprises an equivalent of sub-pixel 426, an equivalent of sub-pixel 428, and an equivalent of sub-pixel 430. Each corner of equivalent sub-pixels is at the same position relative to a respective sub-pixel center. For instance, as shown in FIG. 4B, static corner 426 of sub-pixel 426 is a distance “D1” from the center of sub-pixel 426, static corner 428 of sub-pixel 428 is a distance “D2” from the center of sub-pixel 428, and static corner 430 of sub-pixel 430 is a distance “D3” from the center of sub-pixel 430. In another pixel of display portion 406 (not shown in FIG. 4B for brevity) static corners equivalent to static corners 426, 428, and 430 would be in the same positions relative to respective sub-pixel centers at respective distances D1, D2, and D3.

Pixel 424 is a further example of pixel 214A and/or pixel 214n, as described with respect to FIGS. 2 and 3. As shown in FIG. 4B, each of sub-pixels 432-436 comprise static corners (represented with squares) and dynamic corners (represented with circles). Each static corner of sub-pixels of display portion 204 are in the same position relative to respective sub-pixel centers as the static corners of respective sub-pixels 432-436. For instance, suppose each pixel of display portion 204 includes a pixel similar to pixel 424 with three sub-pixels similar to sub-pixels 432-436. In this example, static corners of sub-pixels similar to sub-pixel 432 are in the same relative position to a respective sub-pixel center, static corners of sub-pixels similar to sub-pixel 434 are in the same relative position to a respective sub-pixel center, and static corners of sub-pixels similar to sub-pixel 436 are in the same relative position to a respective sub-pixel center. For instance, as shown in FIG. 4B, static corner 432 of sub-pixel 432 is a distance “D4” from the center of sub-pixel 432, static corner 434 of sub-pixel 434 is a distance “D5” from the center of sub-pixel 434, and static corner 436 of sub-pixel 436 is a distance “D6” from the center of sub-pixel 436. In another pixel of display portion 404 (not shown in FIG. 4B for brevity) static corners equivalent to static corners 432, 434, and 436 would be in the same positions relative to respective sub-pixel centers at respective distances D4, D5, and D6.

The position of each of the dynamic corners of sub-pixels 432-436 is located such that the shape of the sub-pixels of pixel 424 are different from the shape of (at least one of) the other pixels of display portion 404. By locating positions of dynamic corners of sub-pixels in a manner such that the sub-pixels are different shapes in this way, the angles of edges of adjacent sub-pixels with respect to one another are irregular (e.g., not periodic). The irregularity of these angles causes the PSF of light passing through display portion 404 to have lower energy lines, thereby reducing or removing visual artifacts that appear in images taken by a UDC. Furthermore, the irregularity of scattering of light passing through display portion 404 causes scattered light captured by an under display camera to appear as noise. In accordance with an embodiment, and as described further with respect to FIGS. 13 and 14, by causing scattered light to appear as noise, display portion 404 improves image processing techniques' capability to filter visual artifacts caused by the scattered light. This further improves the image quality of a processed image generated by a display device with an under display camera.

Pixels 422 and 424 are illustrated in and described with respect to FIG. 4B as comprising three sub-pixels; however, implementations of pixels 422 and 424 may include any number of sub-pixels. Furthermore, sub-pixels 426-436 are illustrated in and described with respect to FIG. 4B as hexagon in shape; however, implementations of pixels 426-436 may be in the shape of a circle, an ellipse, a fan, a dumbbell, a pear, a quadrilateral, a pentagon, a quasi-rectangle, a rounded rectangle, a trapezoid, a quasi-trapezoid, a rounded trapezoid, star, a heart, and/or in any other type of shape suitable for a sub-pixel in a display panel, as would be understood by a person ordinarily skilled in the relevant art(s) having benefit of this disclosure. Further still, sub-pixels within a pixel may be in different shapes (e.g., red sub-pixels are square shaped, green sub-pixels are square shaped, and blue pixels are rectangular shaped; red sub-pixels are trapezoidal in shape, green sub-pixels are trapezoidal in shape, and blue pixels are square shaped; and/or any other combination of shapes suitable for use in a display panel). The square and circle corners shown in FIG. 4B are for illustrative clarity. Embodiments of sub-pixels 426-436 may have regular corners, chamfered corners, filleted corners, or any other type of corners (e.g., irregular corners due to manufacturing tolerances).

To better understand embodiments of sub-pixel designs with dynamic and static corners, FIG. 5 will now be described. FIG. 5 shows a block diagram of a pixel pattern 500, according to an example embodiment. In accordance with an embodiment, pixel pattern 500 represents a close-up view of four pixels of display portion 212 of FIG. 2 and/or display portion 404 of FIG. 4A. Pixel pattern 500 includes sub-pixels 502A-502D, sub-pixels 504A-504D, and sub-pixels 506A-506D. Sub-pixels 502A-502D are further examples of sub-pixels 216A or 218A, sub-pixels 504A-504D are further examples of sub-pixels 216B or 218B, and sub-pixels 506A-506D are further examples of sub-pixels 216n or 218n. Sub-pixels of sub-pixels 502A-502D, 504A-504D, and 506A-506D may be grouped as pixels or pixel units. For instance, sub-pixel 502A, 504A, and 506A may be grouped as “Pixel A,” sub-pixel 502B, 504B, and 506B may be grouped as “Pixel B,” sub-pixel 502C, 504C, and 506C may be grouped as “Pixel C,” and sub-pixel 502D, 504D, and 506D may be grouped as “Pixel D.” In accordance with an embodiment, sub-pixels 502A-502D emit a first color of light (e.g., red light), sub-pixels 504A-504D emit a second color of light (e.g., green light), and sub-pixels 506A-506D emit a third color of light (e.g., blue light).

Sub-pixels 502A-502D, 504A-504D, and 506A-506D each comprise a respective sub-pixel center, three respective static corners, and three respective dynamic corners. For instance, sub-pixels 502A-502D comprise a respective center of centers 508A-508D, a respective static corner of static corners 514A-514D, of static corners 516A-516D, and of static corners 518A-518D, and a respective dynamic corner of dynamic corners 532A-532D, of dynamic corners 534A-534D, and of dynamic corners 536A-536D. Each of sub-pixels 504A-504D comprise a respective center of centers 510A-510D, a respective static corner of static corners 520A-520D, of static corners 522A-522D, and of static corners 524A-524D, and a respective dynamic corner of dynamic corners 538A-538D, of dynamic corners 540A-540D, and of dynamic corners 542A-542D. Each of sub-pixels 506A-506D comprise a respective center of centers 512A-512D, a respective static corner of static corners 526A-526D, of static corners 528A-528D, and of static corners 530A-530D, and a respective dynamic corner of dynamic corners 544A-544D, of dynamic corners 546A-546D, and of dynamic corners 548A-548D.

The positions of static corners of sub-pixels 502A-502D, 504A-504D, and 506A-506D, are located such that respective static corners of sub-pixels of the same type (e.g., same color, same position with respect to the pixel unit's center, etc.) are in the same position relative to respective sub-pixel center. For instance, positions of static corners 514A, 514B, 514C, and 514D are located such that each are in the same position relative to respective sub-pixel centers 508A, 508B, 508C, and 508D.

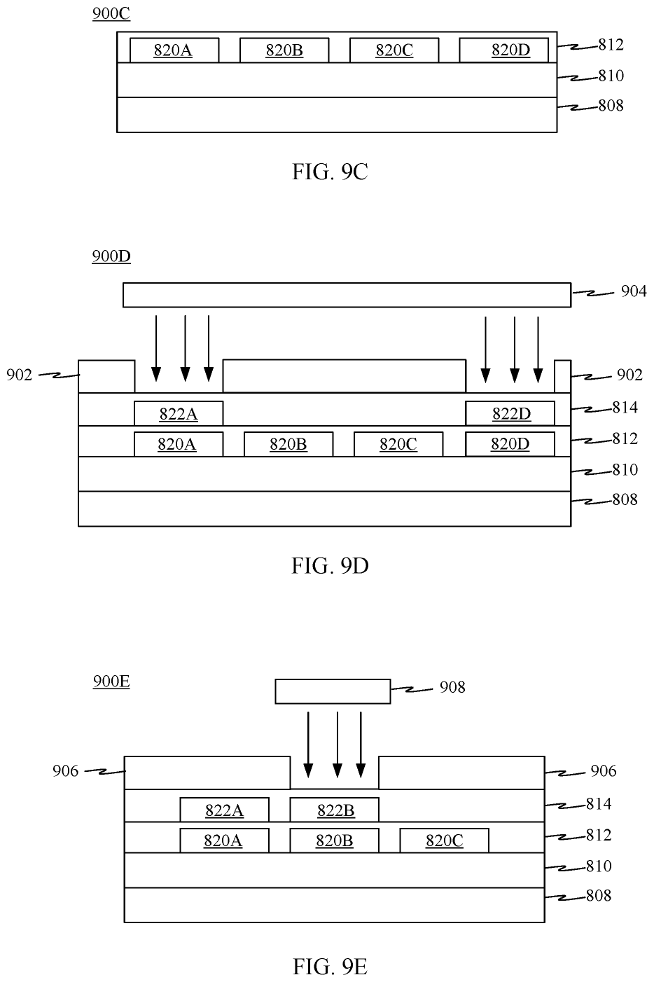

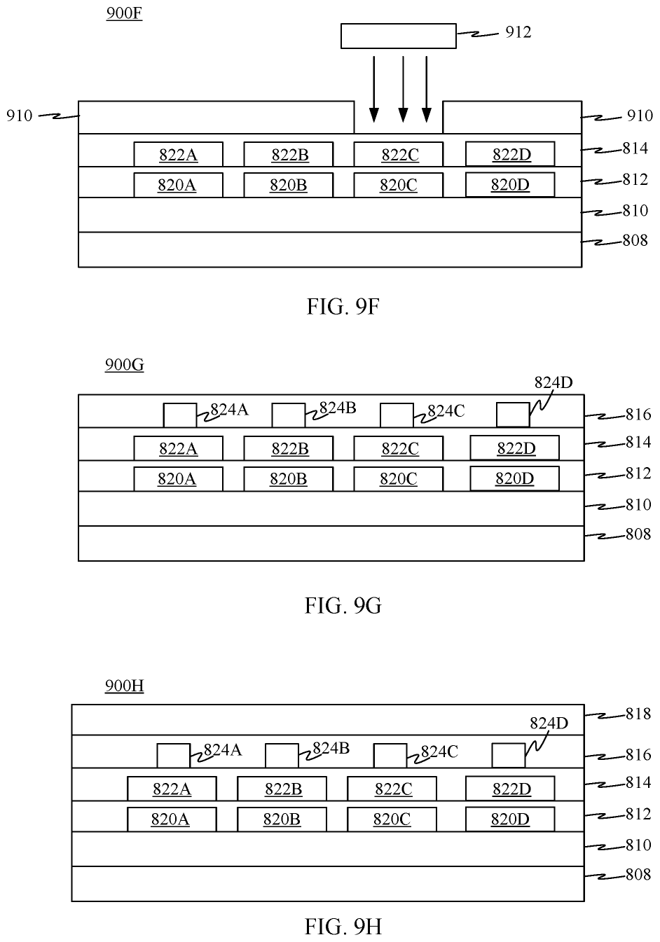

The positions of dynamic corners of sub-pixels 502A-502D, 504A-504D, and 506A-506D are located such that shapes of respective sub-pixels of the same type (e.g., the same color and/or the same position relative to a respective pixel unit's center) are different from each other. For example, as shown in FIG. 5: the positions of dynamic corners 532A-532D, 534A-534D, and 536A-536D are located such that the shapes of sub-pixels 502A-502D are different from each other; the positions of dynamic corners 538-538D, 540A-540D, and 542A-542D are located such that the shapes of sub-pixels 504A-504D are different from each other; and the positions of dynamic corners 544A-544D, 546A-546D, and 548A-548D are located such that the shapes of sub-pixels 506A-506D are different from each other. In accordance with an embodiment, the positions of dynamic corners 544A-544D, 546A-546D, and 548A-548D are randomly selected using a randomization algorithm. Alternatively, the positions of dynamic corners 544A-544D, 546A-546D, and 548A-548D are selected using a non-random algorithm. In accordance with an embodiment, the positions of dynamic corners 544A-544D are selected during manufacture of sub-pixels 502A-502D, 504A-504D, and 506A-506D. For instance the positions are selected using a mask (e.g., a fine metal mask). Further details regarding the manufacture of sub-pixels and use of masks are discussed with respect to FIGS. 9A-12C, as well as elsewhere herein. By locating positions of dynamic corners such that the shapes of sub-pixels are different from each other, the angles of subpixel edges are irregular, randomized, or otherwise reduced in periodicity, thereby reducing visual artifacts in images captured by an under display camera caused by light scattering as it passes through the display panel comprising sub-pixels 502A-502D, 504A-504D, and 506A-506D.

To better understand the features of sub-pixels of pixel pattern 500, FIGS. 6A and 6B will now be described. FIG. 6A shows a block diagram of a portion 600A of pixel pattern 500 of FIG. 5, according to an example embodiment. FIG. 6B shows a block diagram of a portion 600B of pixel pattern 500, according to an example embodiment. In particular, portion 600A is a close-up view of sub-pixels 502A, 504A, and 506A of Pixel A, and portion 600B is a close-up view of pixels 502B, 504B, and 506B of Pixel B. Further structural and operational embodiments will be apparent to persons skilled in the relevant art(s) based on the following description of FIGS. 6A and 6B with respect to FIG. 5.

As shown in FIG. 6A, portion 600A shows a pixel center 614 of Pixel A, center 508A, static corner 516A, dynamic corner 534A, and static corner 518A of sub-pixel 502A, center 510A, static corner 520A, dynamic corner 538A, and static corner 522A of sub-pixel 504A, and center 512A, static corners 526A, 528A, and 530A, and dynamic corners 544A, 546A, and 548A of sub-pixel 506A. As shown in FIG. 6B, portion 600B shows a pixel center 616 of Pixel B, center 508B, static corner 516B, dynamic corner 534B, and static corner 518B of sub-pixel 502B, center 510B, static corner 520B, dynamic corner 538B, and static corner 522B of sub-pixel 504B, and center 512B, static corners 526B, 528B, and 530B, and dynamic corners 544B, 546B, and 548B of sub-pixel 506B. Pixel center 614 and pixel center 616 are respective (imaginary) center points of Pixel A and Pixel B. In FIG. 6A, pixel center 614 is (approximately) a central point between sub-pixel centers 508A, 510A, and 512A (e.g., a center of an imaginary triangle with corners located at sub-pixel centers 508A, 510A, and 512A, not shown in FIG. 6A for illustrative clarity). In FIG. 6B, pixel center 616 is (approximately) a central point between sub-pixel centers 508B, 510B, and 512B (e.g., a center of an imaginary triangle with corners located at sub-pixel centers 508B, 510B, and 512B, not shown in FIG. 6B for illustrative clarity). With respect to FIGS. 6A and 6B, center 508A and pixel center 614 have a same relative positional relationship as center 508B and pixel center 616, center 510A and pixel center 614 have the same relative positional relationship as center 510B and pixel center 616, and center 512A and pixel center 614 have the same relative positional relationship as center 512B and pixel center 616. By having sub-pixel centers of the same type have the same relative positional relationship with respective pixel centers, complexity of the manufacturing of a display panel including Pixel A and Pixel B (e.g., display panel 206 of FIG. 2) is reduced. Furthermore, having sub-pixel centers of the same type have the same relative positional relationship with respective pixel centers provides points of reference for an algorithm (or other method) used to select positions of dynamic corners in a manner that reduces or removes visual artifacts that appear in images taken by a UDC and/or increases the area of the sub-pixel (thereby improving the lifespan of the sub-pixel).

As stated elsewhere herein, static corners are corners at a same position relative to a respective sub-pixel center. In some embodiments, having the static corners at a same position relative to a respective sub-pixel center enables greater control over the irregularity in angles between adjacent sub-pixels. Moreover, complexity in the pixel design and manufacturing process is reduced since (e.g., only) positions of the dynamic corners are selected (e.g., using an algorithm) whereas positions of static corners remain the same for the particular pixel pattern. With respect to FIGS. 6A and 6B, static corners 516A and 516B are at a same position relative to respective sub-pixel centers 508A and 508B, static corners 518A and 518B are at a same position relative to sub-pixel centers 508A and 508B, static corners 520A and 520B are at a same position relative to sub-pixel centers 510A and 510B, static corners 522A and 522B are at a same position relative to sub-pixel centers 510A and 510B, static corners 526A and 526B are at a same position relative to sub-pixel centers 512A and 512B, static corners 528A and 528B are at a same position relative to sub-pixel centers 512A and 512B, and static corners 530A and 530B are at a same position relative to sub-pixel centers 512A and 512B. For instance (and as illustrative examples), as shown in FIGS. 6A and 6B, static corner 518A and static corner 518B are both a distance “D7” from respective centers 508A and 508B, static corner 520A and static corner 520B are both a distance “D8” from respective centers 510A and 510B, and static corner 530A and static corner 530B are both a distance “D9” from respective centers 512A and 512B.

As stated elsewhere herein, dynamic corners are corners located such that a shape of a first sub-pixel is different from the shape of a second sub-pixel (e.g., wherein the first and second sub-pixels emit the same color of light in respective pixel units and/or wherein centers of the first and second sub-pixels have a same relative positional relationship to centers of their respective pixel units). For instance, with respect to FIGS. 6A and 6B, the position of dynamic corner 534A and the position of dynamic corner 534B are located such that the shape of sub-pixel 502A is different from the shape of sub-pixel 502B. Furthermore, the position of dynamic corner 538A and the position of dynamic corner 538B are located such that the shape of sub-pixel 504A is different from the shape of sub-pixel 504B. Still further, the positions of dynamic corners 544A, 546A, and 548A and the position of dynamic corners 544B, 546B, and 548B are located such that the shape of sub-pixel 506A is different from the shape of sub-pixel 506B.

To better illustrate the location of positions of dynamic corners 534A, 534B, 538A, 538B, 544A, 544B, 546A, 546B, 548A, and 548B causing the shapes of sub-pixel 502A to be different from the shape of sub-pixel 502B, the shape of sub-pixel 504A to be different from the shape of sub-pixel 504B, and the shape of sub-pixel 506A to be different from the shape of sub-pixel 506B, FIGS. 6A and 6B include illustrations of imaginary corners representing a position of the respective dynamic corners being in a regular position of a regular configuration of the respective sub-pixel (e.g., the position the corner would be in if it were a static corner (e.g., in the case of a polygonal shaped sub-pixel, the position the corner would be in if the pixel were a regular polygon that is equiangular and equilateral)). For example, FIG. 6A includes imaginary corner 634A at a position representative of the position of dynamic corner 534A in a regular configuration of sub-pixel 502A, imaginary corner 638A at a position representative of the position of dynamic corner 538A in a regular configuration of sub-pixel 504A, and imaginary corners 644A, 646A, and 648A at positions representative of the respective positions of dynamic corners 544A, 546A, and 548A in a regular configuration of sub-pixel 506A. Furthermore, FIG. 6B includes imaginary corner 634B at a position representative of the position of dynamic corner 534B in a regular configuration of sub-pixel 502B, imaginary corner 638B at a position representative of the position of dynamic corner 538B in a regular configuration of sub-pixel 504B, and imaginary corners 644B, 646B, and 648B at positions representative of the respective positions of dynamic corners 544B, 546B, and 548B in a regular configuration of sub-pixel 506B.

In embodiments, the positions of dynamic corners of sub-pixels in different sub-pixels may be adjusted or otherwise located in similar directions. For instance, sub-pixels located in the same relative position with respect to a respective pixel center may have their dynamic corners located to adjust in a similar direction with respect to a sub-pixel center (e.g., increase or decrease a distance from the sub-pixel center) and/or adjust an interior angle of the dynamic corner in a similar direction of magnitude (e.g., increase or decrease the interior angle). As a non-limiting example and as shown in FIG. 6A, the position of dynamic corner 534A is located to increase an interior angle 602A relative to an interior angle 602A of imaginary corner 634A (i.e., the respective dynamic corner 534A in a regular polygon configuration of sub-pixel 502A). Continuing this example with respect to FIG. 6B, the position of dynamic corner 534B is also located to increase an interior angle 608B relative to an interior angle 608A of imaginary corner 634B (i.e., the respective dynamic corner 534B in a regular polygon configuration of sub-pixel 502B). As also shown in FIGS. 6A and 6B, the positions of dynamic corners 538A and 538B are located to decrease respective interior angles 604B and 610B relative to respective interior angles 604A and 610A of imaginary corners 638A and 638B (i.e., the respective dynamic corners 538A and 538B in regular polygon configurations of sub-pixels 504A and 504B). By modifying similar respective dynamic corners of sub-pixels across multiple pixel units, the shapes of sub-pixels are adjusted in a manner that simplifies maintenance of (or increase of) emissive areas (also referred to as “light emitting areas”) of the sub-pixels within a predetermined range and/or maintenance of a pixel definition layer (PDL) gap above a minimum threshold distance. For example, since dynamic corner 538A is located in a particular position that decreases interior angle 604B, dynamic corner 548A is located in a position that increases interior angle 548A to maintain a PDL gap 606 above a minimum threshold distance. In order to ensure the emissive area of sub-pixel 506A is not reduced below a threshold, dynamic corners 544A and 546A are located in a position that decreases interior angles of dynamic corners 544a and 546A to maintain (or increase) the emissive area of sub-pixel 506A within a predetermined range. The shift in dynamic corner 546A impacts the PDL gap between sub-pixel 506A and sub-pixel 504B (e.g., as seen in FIG. 5). Thus, the position of dynamic corner 542B is located to increase the interior angle of dynamic corner 542B to maintain a PDL gap between the respective sub-pixels 506A and 504B above a minimum threshold distance and the position of dynamic corner 538B is located to maintain (or increase) the emissive area of sub-pixel 504B. This pattern reduces the complexity of algorithms used to select positions of dynamic corners (e.g., since a particular dynamic corner for a type of sub-pixel will be positioned in a similar (e.g., but not the same) position for each sub-pixel). Therefore, the manufacture of display panels that include sub-pixels 502A, 502B, 504A, 504B, 506A, and 506B (as well as other pixels and sub-pixels manufactured in a similar manner) is simplified and maintains (or improves) the functionality of the display panel (e.g., since the emissive areas of the sub-pixels are maintained within a predetermined range the quality of images captured by an under display camera are improved without reducing the lifespan of sub-pixels).

Example dynamic corners 534A and 534B and dynamic corners 538A and 538B have been described with respect to increasing or decreasing interior angles with respect to interior angles of regular configurations of the dynamic corners, it is also contemplated herein that dynamic corners may be adjusted in other ways as well. For instance, positions of respective dynamic corners of sub-pixels of a same type (e.g., located in the same position relative to a respective pixel unit center and/or emitting the same color of light) may be located to increase or decrease a distance from a respective sub-pixel center. For instance, in an alternative embodiment with respect to FIGS. 6A and 6B, positions of corners 534A and 534B are located to decrease a distance from respective sub-pixel centers 508A and 508B relative to respective distances of imaginary corners 634A and 634B from respective sub-pixel centers 508A and 508B. In this alternative embodiment, positions of corners 538A and 538B are located to increase a distance from respective sub-pixel centers 510A and 510B relative to respective distances of imaginary corners 638A and 638B from respective sub-pixel centers 510A and 510B. This enables similar adjustments to dynamic corners wherein interior angles remain the same as regular configurations of the dynamic corners or wherein the interior angles increase or decrease in the opposing magnitudes (e.g., dynamic corners 534A and 534B may both be located to be closer to respective sub-pixel centers 508A and 508B relative to imaginary corners 634A and 634B, but interior angle 602B increases relative to interior angle 602A and interior angle 608B decreases relative to interior angle 608A) while simplifying manufacture of and/or maintaining (or improving) functionality of a display panel that includes sub-pixels 502A, 502B, 504A, and 504B.

In another alternative embodiment, positions of respective dynamic corners of sub-pixels of a same type are located such that the corner is outside or inside an imaginary boundary (i.e., perimeter) of a regular configuration of the sub-pixel. For instance, the perimeters of regular configurations of sub-pixels 502A, 504A, and 506A and 502B, 504B, and 506B are shown as dashed lines in FIGS. 6A and 6B respectively. In an example of this alternative embodiment, the positions of corners 534A and 534B are located within the perimeter of the respective regular configurations of sub-pixels 502A and 502B and the positions of corners 538A and 538B are located outside the perimeter of the respective regular configurations of sub-pixels 504A and 504B. This enables similar adjustments to dynamic corners wherein interior angles remain the same as regular configurations of the dynamic corners or wherein the interior angles increase or decrease in the opposing magnitudes (e.g., dynamic corners 538A and 538B may both be located to be outside the perimeter of the respective regular configurations of sub-pixels 504A and 504B, but interior angle 604B decreases relative to interior angle 604A and interior angle 610B increases relative to interior angle 610A) while simplifying manufacture of and/or maintaining (or improving) functionality of a display panel that includes sub-pixels 502A, 502B, 504A, and 504B.

During the manufacturing process of a display panel, a PDL is used to prevent electrical shorts between anodes of sub-pixels and pixels. The PDL also prevents organic material from one sub-pixel from mixing with organic material from another sub-pixel. Depending on the implementation, the distance between the sub-pixels, also referred to as the “PDL gap,” may have a minimum distance. In some implementations, the minimum distance is a limitation of the manufacturing process. In accordance with an embodiment, the positions of dynamic corners of adjacent pixels are located to maintain the PDL gap above a minimum distance threshold. For instance, as shown with respect to FIGS. 6A and 6B the positions of dynamic corners 538A and 548A are located such that PDL gap 606 is above a minimum threshold and the positions of dynamic corners 538B and 548B are located such that a PDL gap 612 is above a minimum threshold. In particular, the positions of dynamic corners 538A and 538B are located to decrease respective interior angles 604B and 610B relative to interior angles 604A and 610A and the positions of dynamic corners 548A and 548B are located to increase respective interior angles 622B and 624B relative to interior angles 622A and 622A of respective imaginary corners 648A and 648B (i.e., the respective dynamic corners 548A and 548B in regular polygon configurations of sub-pixels 506A and 506B). In this context, the position of dynamic corner 548A is located far enough away from dynamic corner 538A such that PDL gap 606 is wider than a minimum threshold and the position of dynamic corner 548B is located far enough away from dynamic corner 538B such that PDL gap 612 is wider than the minimum threshold. By adjusting dynamic corners in this manner, embodiments described herein provide irregular angles between edges of adjacent sub-pixels without requiring the light emitting area of a sub-pixel to be reduced. For instance, suppose Pixel A and Pixel B are illustrated with respect to an imaginary horizontal axis (not shown in FIGS. 6A and 6B for illustrative clarity). Further suppose the angle of the edges between dynamic corner 538A and static corner 522A and between dynamic corner 548A and static corner 530A are at a different angle with respect to the horizontal axis than the angle of the edges between dynamic corner 538B and static corner 522B and between dynamic corner 548B and static corner 530B. This irregularity of angles causes the PSF of light passing through PDL gap 606 and PDL gap 612 to have lower energy lines (e.g., compared to if the positions of dynamic corners 538A, 538B, 548A, and 548B were in a regular configuration), thereby reducing or removing visual artifacts that appear in images taken by a UDC positioned opposite of sub-pixels 504A, 504B, 506A, and 506B.

In some embodiments of sub-pixel designs described herein, the position of dynamic corners of a sub-pixel are located such that the area of the sub-pixel (e.g., the light emitting area of the sub-pixel) is within a predetermined range relative to the area of a regular configuration of the sub-pixel. As an illustrative example with respect to FIG. 6A, sub-pixel 506A includes dynamic corners 544A, 546A, and 548A. The position of dynamic corner 548A is located to fall within the perimeter of the regular configuration of sub-pixel 506A. In this case, if only dynamic corner 548A were located in this way and the regular positions of dynamic corners 544A and 546A (i.e., the positions of imaginary corners 644A and 646A, respectively) were located, the area of sub-pixel 506A would be reduced relative to a regular configuration of sub-pixel 506A. In order to preserve the area of sub-pixel 506A, the positions of dynamic corners 544A and 546A are located such that the area of sub-pixel 506A is within a predetermined range of the area of the regular configuration of sub-pixel 506A. In accordance with a non-limiting example embodiment, the positions of dynamic corners of sub-pixels are located to maintain sub-pixel areas within 5% of the area of the regular configuration of the respective sub-pixel; however, other ranges may be used (e.g., within 1%, less than 1%, less than 10%, etc.). Furthermore, the upper and lower boundaries of the predetermined range may be different. For instance, dynamic corners may be located such that a minimum sub-pixel area is no smaller than a first threshold (e.g., 1% smaller, 5% smaller, etc.) and a maximum sub-pixel area is no greater than a second threshold (e.g., 1% greater, 5% greater, etc.). Further still, in some embodiments the minimum boundary and/or the maximum boundary of the predetermined range is the area of the regular configuration of the sub-pixel (i.e., 0% smaller and/or greater than the area of the regular configuration). In some embodiments, different ranges and/or thresholds are used for different types of sub-pixels (e.g., a larger sub-pixel in a pixel unit may have a smaller percentage the area of the sub-pixel is allowed to deviate from the regular configuration of the sub-pixel compared to a smaller sub-pixel in the pixel unit). By keeping the pixel area at least above a minimum threshold, embodiments described herein are able to have irregular angles of sub-pixel edges with little or no impact to the life of the sub-pixel. For instance, if the area of a sub-pixel was too low (e.g., below a minimum threshold) that sub-pixel's lifespan would be reduced because a higher current density would be needed in order to have the same brightness as other pixels (e.g., static pixels) in the display. Over time, the sub-pixel would get dimmer due to wear. Thus, embodiments of the present disclosure are able to have irregular angles without sacrificing the lifespan of a sub-pixel and maintain emissive area uniformity across sub-pixels. Furthermore, if the area of a sub-pixel is increased compared to the regular configuration of the sub-pixel, the sub-pixel may achieve the same brightness as other sub-pixels (e.g., sub-pixels in a static or regular configuration) at a lower current density, thereby improving the lifespan of the sub-pixel.

As described herein, in some embodiments, positions of dynamic corners are located based on an algorithm (e.g., a randomization algorithm). In an embodiment the algorithm is used to select positions of dynamic corners during manufacture of the sub-pixels. Alternatively, the algorithm is used to select positions of dynamic corners during manufacture (or design) of a mask used to manufacture the sub-pixels. As a non-limiting example, suppose the dynamic corners of sub-pixels of Pixel A and Pixel B are located based on a randomization algorithm. In this context, the randomization algorithm may be given a set of boundaries as input. As a non-limiting example, suppose the randomization algorithm used to select positions (e.g., during manufacture of Pixel A and Pixel B) of dynamic corners of Pixel A and Pixel B is given a minimum distance for the PDL gaps between sub-pixels (e.g., PDL gap 606, PDL gap 612, and other PDL gaps not shown in FIGS. 6A and 6B for illustrative brevity), a minimum boundary for the area of a sub-pixel, a maximum boundary for the area of a sub-pixel, and a maximum deviation for each dynamic corner. In accordance with an embodiment, the maximum deviation (referred to in this context as a “maximum angle deviation”) is a maximum value of an angle between an edge of the dynamic corner and an adjacent static corner and an imaginary edge of the adjacent static corner and the regular configuration of the dynamic corner. In accordance with an alternative embodiment, the maximum deviation (referred to in this context as a “maximum distance deviation”) is a maximum distance from the regular configuration of the dynamic corner that the dynamic corner is allowed to deviate from.

To better illustrate the embodiment where the maximum deviation is a maximum angle deviation, a non-limiting example will be described with respect to FIGS. 6A and 6B. For instance, with respect to FIGS. 6A and 6B, the maximum angle deviation is such that an angle 618A between an edge of dynamic corner 534A and static corner 518A and an “imaginary edge” of imaginary corner 634A and static corner 518A is no greater than a first predetermined value, and such that an angle 618B between an edge of dynamic corner 534B and static corner 518B and an imaginary edge of imaginary corner 634B and static corner 518B is no greater than the second predetermined value. Furthermore, the maximum angle deviation is such that an angle 620A between an edge of dynamic corner 538A and static corner 520A and an imaginary edge of imaginary corner 638A and static corner 520A is no greater than a second predetermined value, and such that an angle 620B between an edge of dynamic corner 538B and static corner 520B and an imaginary edge of imaginary corner 638B and static corner 520B is no greater than the second predetermined value. In accordance with an embodiment, the first and second predetermined values are the same value (e.g., in degrees or in radians).

In accordance with an embodiment, the algorithm used to select positions of dynamic corners multiplies the maximum deviation by a randomly generated number. For instance, with respect to Pixel A and Pixel B of FIGS. 6A and 6B, suppose the maximum deviation is a maximum angle deviation. In this context, for each dynamic corner, the maximum angle deviation is multiplied by a randomly generated number such that the result falls between zero and the value of the maximum angle deviation (either including or not including zero and/or the value of the maximum angle deviation). The result is applied to at least one of the angles between an edge and an imaginary edge of the dynamic corner and an adjacent static corner. For example, suppose the value of maximum angle deviation is 12 degrees and the random number is a number randomly between 0 and 1. In this example, suppose angle 618A is assigned the value 10.1 degrees and angle 618B is assigned the value 8.55 degrees. Depending on the implementation, an angle associated with an adjacent edge of an adjacent sub-pixel is assigned the same value (e.g., angle 620A is assigned the value 10.1 degrees and angle 620B is assigned the value 8.55 degrees). In this way, the PDL gap between the edges is kept at a minimum value, which increases the possible area of the sub-pixel compared to the angle having a different assigned value. Alternatively, the angle of the adjacent edge of the adjacent sub-pixel is assigned a random number with a maximum value of the angle of the first edge (e.g., angle 620A is assigned a random value as high as 10.1 degrees and angle 620B is assigned a random value as high as 8.55 degrees). In this way, the PDL gap is allowed to fluctuate between a minimum PDL gap value and a PDL gap value if the angle associated with the edge was at a maximum or minimum value (e.g., in the case of angle 620A, if angle 620A were 0 or (if the angle was reversed across the imaginary edge of dynamic corner 538A and static corner 520A)-12 degrees. This allows greater flexibility in the location of the positions of dynamic corners, thereby allowing for further randomization and/or irregularity in angles between sub-pixel edges. As stated elsewhere herein, irregularity in angles between sub-pixel edges reduces the high energy lines of the PSF of light passing through a display area and captured by an under display camera.

With continued reference to the use of an algorithm to randomly select positions of a dynamic corner, the position of the dynamic corner may be selected in various ways. For instance, in the non-limiting running example described above angle 618A is randomly assigned the value 10.1 degrees. In order to determine the position of dynamic corner 534A, an angle 626 between the edge of dynamic corner 534A and static corner 516A and an imaginary edge of imaginary corner 634A and static corner 516A in accordance with an embodiment is also randomly assigned a value by multiplying the maximum angle deviation value (12 degrees) by a random number). In an alternative embodiment, angle 626 is assigned the same value as angle 618A. In another alternative embodiment, the value of angle 626 is a different polarity (e.g., less than zero and greater than or equal to −12) than the value of angle 618A, such that dynamic corner 534A is outside the perimeter of the regular configuration of sub-pixel 202A.

Depending on the implementation, the rest of the dynamic corners of sub-pixels 502A, 502B, 504A, 504B, 506A, and 506B are (e.g., randomly) selected using the same algorithm. Alternatively, a different algorithm is used to select different respective dynamic corners. For instance, in the running example described above, suppose the described algorithm (the “first” algorithm) is used to select any number between 0 and 12 (by multiplying the maximum angle deviation (12) by a randomly generated number between 0 and 1) for each of angles 618A, 618B, 626A, and 626B in order to select the positions of dynamic corners 534A and 534B. Further suppose a second algorithm is used to select positions of dynamic corners 538A, 538B, 548A, and 548B with the values of angles 618A, 618B, 626A, and 626B as respective boundaries in order to keep respective PDL gaps above a minimum PDL gap threshold. Still further suppose a third algorithm is used to select positions of dynamic corners 532A, 532B, 536A, 536B, 542A, 542B, 540A, 540B, 544A, 544B, 546A, and 546B (as shown in FIG. 5, not shown in FIGS. 6A and 6B for illustrative brevity) in order to maintain sub-pixel areas of sub-pixels 502A, 502B, 504A, 504B, 506A, and 506B within a predetermined range. By using different algorithms in this way, the positions of the first dynamic corners may be selected using a (relatively) simpler algorithm (e.g., an algorithm that only uses the maximum deviation value as input) and the positions of the other dynamic corners may be selected such that pixel areas and PDL gaps are within respective ranges such that pixel performance and health are maintained (or improved).

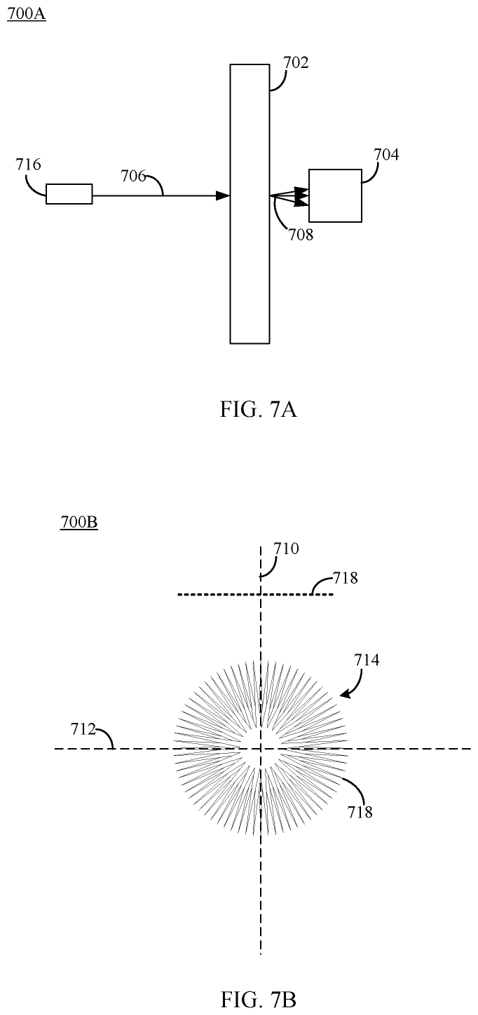

To better illustrate the benefits of sub-pixel designs with static and dynamic corners, FIGS. 7A and 7B will now be described. FIG. 7A shows a block diagram of a system 700A that includes a display panel with modified sub-pixels, according to an example embodiment. FIG. 7B shows a diagram 700B of a point spread function corresponding to system 700A of FIG. 7A, according to an example embodiment. System 700A comprises a display panel 702, a camera 704, and a point source 716. In an embodiment, display panel 702 and camera 704 are incorporated in a single device (e.g., user device 202 of FIG. 2, another computing device, etc.). Display 702 is a further example of display panel 206 (as described with respect to FIGS. 2 and 3) and/or display panel 402 (as described with respect to FIG. 4A). Point source 716 is an example source of light or other object that projects a point of light. Camera 704 is a further example of camera 208 (as described with respect to FIGS. 2 and 3) and/or camera 408 (as described with respect to FIG. 4A). In embodiments, camera 704 captures light from point source 716 that passes through display 702.

For example, as shown in FIG. 7A, point source 716 projects light 706. Light 706 passes through display 702. The pixels and other structures within display 702 (not shown in FIG. 7A) interfere with light 706 and cause it to scatter as scattered light 708. The pixels within display 702 are designed in a manner similar to that described with respect to pixel 424 of FIG. 4B, pixels of pixel pattern 500 of FIG. 5, Pixel A of FIG. 6A, and/or Pixel B of FIG. 6B. In other words, sub-pixels of (at least a first display portion of) display 702 include static and dynamic corners such that shapes of sub-pixels within different pixel units are different from each other and angles between edges of adjacent sub-pixels are irregular. This design causes scattered light 708 to have lower energy lines when captured by camera 704. To illustrate this, FIG. 7B shows a representation of scattered light 708 captured by camera 104 as a point spread function 714 (“PSF 714” herein). PSF 714 is illustrated on a major vertical axis 710 and a major horizontal axis 712. Suppose major vertical and major horizontal axes 710 and 712 are the same magnitude as major vertical and major horizontal axes 110 and 112 of FIG. 1B. Furthermore, FIG. 1B includes a line 718 to illustrate the magnitude of the high energy lines of PSF 114 of FIG. 1B (such as high energy line 118) with respect to PSF 714. As can be seen in FIG. 7B, the magnitude of the energy lines of PSF 714 (such as high energy line 720) is smaller than the magnitude of the energy lines of PSF 114. Thus, the visual artifacts in images captured by camera 704 caused by PSF 714 are reduced in comparison to a camera capturing images formed of light passing through a display that uses sub-pixels without dynamic corners and with periodic edge angles (e.g., as described with respect to camera 104 and display 102 of FIG. 1A).

### III. Example Embodiments of Display Devices and Manufacturing of Display Panels

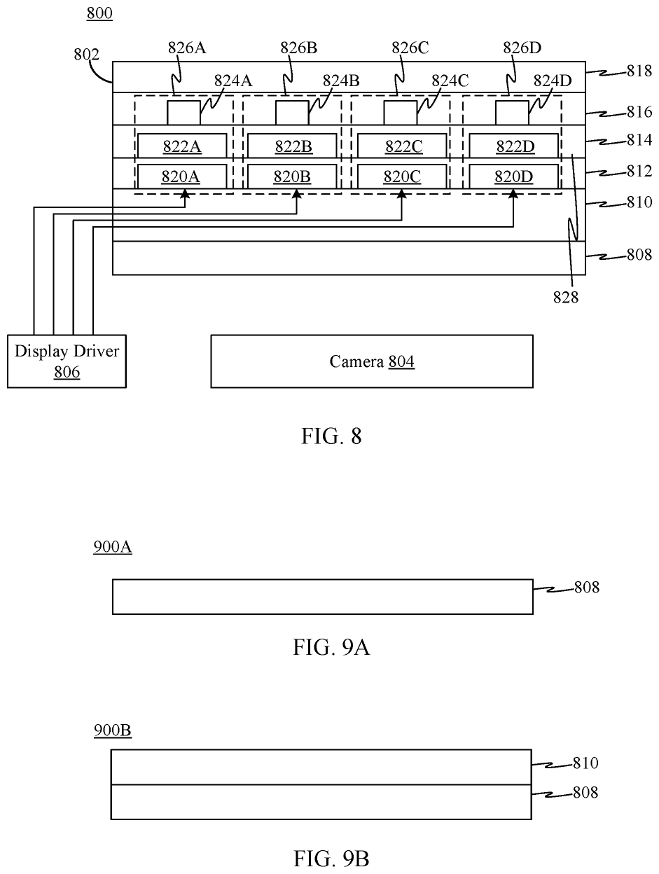

Embodiments of display panels with sub-pixels designed to include static and dynamic corners may be manufactured in various ways. For instance, FIG. 8 shows a block diagram of a display device 800 comprising modified sub-pixels, according to an example embodiment. Display device 800 is a further example of display device 204, as described with respect to FIGS. 2 and 3. As shown in FIG. 8, display device 800 includes a display panel 802, a camera 804, and a display driver 806, each of which are respective further examples of display panel 206, camera 208, and display driver 310 as described with respect to FIG. 3. Display panel 802 comprises a substrate layer 808, a backplane layer 810, an anode layer 812 (comprising a major surface 828), an emissive material layer 814, a cathode layer 816, and an encapsulation layer 818 (collectively referred to as “layers of display panel 802”). Depending on the implementation a layer of display panel 802 may be coupled to another layer of display panel 802 by an adhesive, by being deposited onto the another layer (e.g., through a vapor deposition process), by being etched into the another layer, by being electrically coupled to the another layer, and/or otherwise be coupled to the layer as would be understood by a person ordinarily skilled in the relevant art(s) having benefit of this disclosure. In some embodiments, display panel 802 includes other layers and/or sub-layers not shown in FIG. 8 (e.g., a back plate, additional substrate layers, etc.). In some embodiments, display panel 802 does not include one of the layers shown in FIG. 8 or two layers are combined into a single layer (e.g., anode layer 812 is a sub-layer of backplane layer 810). In some embodiments, a layer of display panel 802 is in a different position relative to the other layers (e.g., substrate layer 808 is located between backplane layer 810 and anode layer 812).

As shown in FIG. 8, anode layer 812 comprises anodes 820A, 820B, 820C, and 802D, emissive material layer 814 comprises organic materials 822A, 822B, 822C, and 822D, and cathode layer 816 comprises cathodes 824A, 824B, 824C, and 824D. Anode 820A, organic material 822A, and cathode 824A form a first sub-pixel 826A, anode 820B, organic material 822B, and cathode 824B form a second sub-pixel 826B, anode 820C, organic material 822C, and cathode 824C form a third sub-pixel 826C, and anode 820D, organic material 822D, and cathode 824D form a fourth sub-pixel 826D. Sub-pixels 826A, 826B, and 826C collectively form a pixel (or “pixel unit”). Sub-pixel 826D is the same type as sub-pixel 826A in a different pixel. Sub-pixel 826A is a further example of sub-pixel 502A, sub-pixel 826B is a further example of sub-pixel 504A, and sub-pixel 826C is a further example of sub-pixel 506A, as described with respect to FIGS. 5 and 6A. Sub-pixel 826D is a further example of sub-pixel 502B as described with respect to FIGS. 5 and 6B. In accordance with an embodiment, sub-pixels 826A and 826D emit a first color of light (e.g., red light), sub-pixel 826B emits a second color of light (e.g., green light), and sub-pixel 826C emits a third color of light (e.g., blue light).

Backplane layer 810 comprises electrical circuits and/or traces for controlling sub-pixels 826A-826D. In accordance with an embodiment, backplane layer 810 includes thin-film transistors (TFTs) for controlling sub-pixels 826A-826D (not shown in FIG. 8). The TFTs may be located proximate to respective sub-pixels 826A-826D. Alternatively, the TFTs are located such that interference with light passing through display panel 802 to camera 804 by the TFTs is reduced or eliminated. In this context, backplane layer 810 comprises traces from the TFTs to the respective sub-pixels 826A-826D. In any case, display driver 806 controls current to sub-pixels 826A-826D using the electrical circuits and traces.

In embodiments, anode layer 812 and emissive material layer 814 include a PDL material (not shown in FIG. 8) that defines the shape of sub-pixels 826A-826D. Encapsulation layer 818 is configured to cover and protect the other layers of display panel 802. In accordance with an embodiment, encapsulation layer 818 includes a protective sub-layer and a display cover window.

Display panel 802 of FIG. 8 may be manufactured in various ways. For instance, display panel 802 in accordance with an embodiment is manufactured using a vapor deposition process. To better understand an example vapor deposition process for manufacturing display panel 802, FIGS. 9A-9H will now be described. FIGS. 9A-9H show respective steps 900A-900H in a manufacturing process of display panel 802 of FIG. 8, according to an example embodiment. In step 900A of FIG. 9A, substrate layer 808 is provided. In accordance with an embodiment, substrate layer 808 is a glass substrate; however, embodiments described herein are not so limited. In accordance with an embodiment, substrate layer 808 is formed or otherwise coupled to a back plate not shown in FIG. 9A for brevity.

In step 900B of FIG. 9B, backplane layer 810 is formed or otherwise coupled to substrate layer 808. As described with respect to FIG. 8, backplane layer 810 in accordance with an embodiment includes TFTs and/or traces used to control sub-pixels of display panel 802. In step 900C of FIG. 9C, anode layer 812 is formed or otherwise coupled to backplane layer 812. Prior to step 900C or as a sub-step of step 900C a PDL layer (not shown in FIG. 9C) is formed to prevent anodes 820A-820C from short circuiting.

In steps 900D-900F of FIGS. 9D-9F, emissive material layer 814 is formed through vapor deposition on anode layer 812. For example, in step 900D of FIG. 9D, display panel 802 is placed in a vacuum. A mask 902 (e.g., a fine metal mask (FMM)) is placed over display panel 802. Mask 902 includes fine holes corresponding to where sub-pixels of a first type (e.g., sub-pixels 826A and 822D) are to be located in display panel 802. To-be-evaporated organic material 904 is heated in the vacuum to cause organic material 904 to evaporate through holes of mask 902 and bond to anode layer 812 to form deposited organic material 822A and deposited organic material 822D. Vapor deposition is repeated in step 900E of FIG. 9E using a mask 906 (which includes fine holes corresponding to where sub-pixels of a second type (e.g., sub pixel 826B) are to be located in display panel 802) placed over display panel 802 and evaporating organic material 908 in the vacuum to cause organic material 908 to bond to anode layer 812 to form deposited organic material 822B. Vapor deposition is repeated in step 900F of FIG. 9F using a mask 910 (which includes fine holes corresponding to where sub-pixels of a third type (e.g., sub pixel 826C) are to be located in display panel 802) placed over display panel 802 and evaporating organic material 912 in the vacuum to cause organic material 908 to bond to anode layer 812 to form deposited organic material 822C.

In step 900G, cathode layer 816 is formed by applying a cathode 824A to organic material 822A, a cathode 824B to organic material 822B, a cathode 824C to organic material 822C, and a cathode 824D to organic material 822D. In step 900H, an encapsulation process is performed to encapsulate display 802 using encapsulation layer 818. In accordance with an embodiment, a protective sub-layer is applied to cathode layer 816 and a display cover window is applied to the protective sub-layer to form encapsulation layer 818.

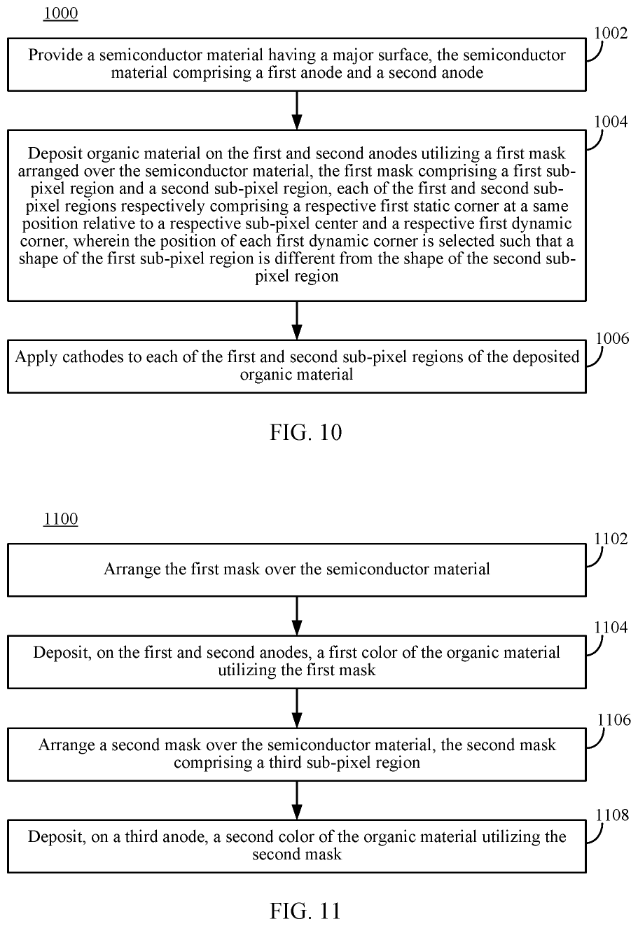

Thus, an example manufacturing process has been described with respect to FIGS. 8 and 9A-9H. Embodiments of display panels may be manufactured in various ways. For instance, FIG. 10 shows a flowchart 1000 of a process for manufacturing a semiconductor device, according to an example embodiment. Flowchart 1000 is a further embodiment of steps 900A-900H of FIGS. 9A-9H, in an embodiment. Flowchart 1000 may be performed to manufacture display panel 206 of FIGS. 2 and 3, display panel 402 of FIG. 4A, display panel 702 of FIG. 7A, display panel 802 of FIG. 8, and/or any other display panel that comprises modified sub-pixels described herein. Note that not all steps of flowchart 1000 need be performed in all embodiments. Further structural and operational embodiments will be apparent to persons skilled in the relevant art(s) based on the following description of FIG. 10 with respect to FIGS. 8 and 9A-9H.

Flowchart 1000 starts with step 1002. In step 1002, a semiconductor material having a major surface is provided. The semiconductor material comprises a first anode and a second anode. For example, anode layer 812 of FIG. 8 is a semiconductor material having a major surface 828 and comprising a first anode 820A and a second anode 820D.

Flowchart 1000 continues to step 1004, which may be a further embodiment of step 900D of FIG. 9D. In step 1004, organic material is deposited on the first and second anodes utilizing a first mask arranged over the semiconductor material. The first mask comprises a first sub-pixel region and a second sub-pixel region. Each of the first and second sub-pixel regions respectively comprise a respective first static corner at a same position relative to a respective sub-pixel center and a respective first dynamic corner, wherein the position of each first dynamic corner is located such that a shape of the first sub-pixel region is different from the shape of the second sub-pixel region. For example, organic materials 822A and 822D of FIG. 8 are deposited onto anode 820A using mask 902 (as shown in FIG. 9D). Mask 902 comprises holes (e.g., a first sub-pixel region and a second sub-pixel region) with static corners and dynamic corners. Respective static corners of holes of mask 902 are located in the same positions relative to respective sub-pixel centers (e.g., in a similar manner to static corners of sub-pixels 502A and 502B as described with respect to FIGS. 5, 6A, and 6B. Respective dynamic corners of holes of mask 902 are located in positions such that shapes of the first and second sub-pixel regions are different from each other. Thus, when organic material 904 is evaporated and passes through mask 902, the shapes of deposited organic materials 822A and 822D are different from each other. By locating positions of dynamic corners of sub-pixel regions of masks in a manner such that the sub-pixel regions of the mask are different shapes in this way, the angles of edges of deposited sub-pixels are irregular (e.g., not periodic). The irregularity of these angles causes the PSF of light passing through display panel 802 to have lower energy lines, thereby reducing or removing visual artifacts that appear in images taken by camera 804.

Flowchart 1000 ends with step 1006, which may be a further embodiment of step 900G of FIG. 9G. In step 1006, cathodes are applied to each of the first and second sub-pixel regions of the deposited organic material. For example, cathode 824A is applied to deposited organic material 822A and cathode 824A is applied to deposited organic material 822D.

In embodiments, pixels of a display panel may include multiple sub-pixels that emit different colors of light. To prevent organic material from sub-pixels that emit one color of light from mixing with sub-pixels that emit another color of light, different masks may be used during the vapor deposition process for each color of organic material. A manufacturing process may utilize different masks in various ways, in embodiments. For example, FIG. 11 shows a flowchart 1100 of a process for depositing organic material, according to an example embodiment. Flowchart 1100 is a further embodiment of 1004 of flowchart 1000 of FIG. 10, in an embodiment. Flowchart 1100 may be performed to manufacture display panel 206 of FIGS. 2 and 3, display panel 402 of FIG. 4A, display panel 702 of FIG. 7A, display panel 802 of FIG. 8, and/or any other display panel that comprises modified sub-pixels described herein. Note that not all steps of flowchart 1100 need be performed in all embodiments. Further structural and operational embodiments will be apparent to persons skilled in the relevant art(s) based on the following description of FIG. 11 with respect to FIGS. 8 and 9A-9H.

Flowchart 1100 begins with steps 1102 and 1104, which are sub-steps of step 900D of FIG. 9D. In step 1102, the first mask is arranged over the semiconductor material. For example, as shown in FIG. 9D, mask 902 is arranged over anode layer 812.

In step 1104, a first color of the organic material is deposited on the first and second anodes utilizing the first mask. For example, as shown in FIG. 9D, organic material 904 is deposited on anodes 820A and 820D as deposited organic material 822A and 822D, respectively. Organic material 904 is a first color (e.g., red).

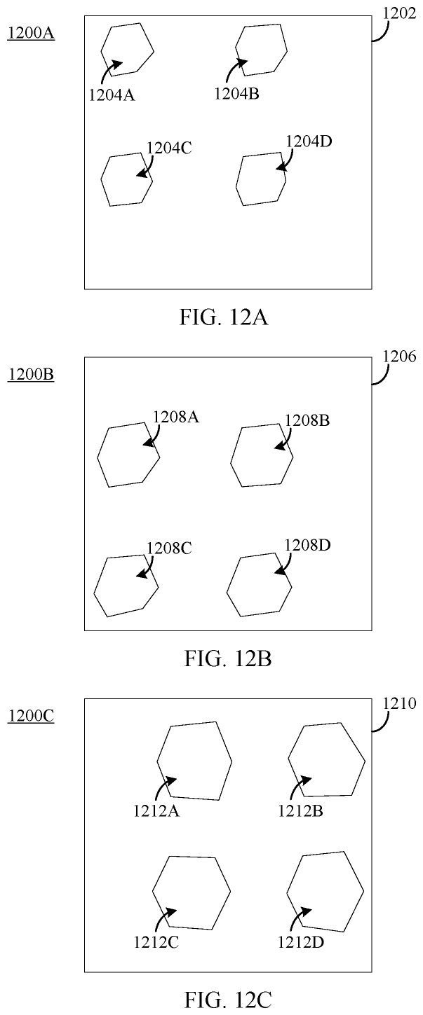

Flowchart 1100 continues to steps 1106 and 1108, which are sub-steps of step 900E of FIG. 9E. In step 1106, a second mask is arranged over the semiconductor material. The second mask comprises a third sub-pixel region. In accordance with an embodiment, the third sub-pixel region comprises a second static corner at a regular position with respect to a sub-pixel center of the third sub-pixel region and a second dynamic corner with a position located such that the third sub-pixel region is different from the shape of another sub-pixel region of the same type. For example, as shown in FIG. 9E, mask 906 is arranged over anode layer 812. As discussed further with respect to FIGS. 12A-12C, and elsewhere herein, mask 906 has holes corresponding to different types of sub-pixel regions than mask 902.

In step 1108, a second color of the organic material is deposited on the third anode utilizing the second mask. For example, as shown in FIG. 9E, organic material 908 is deposited on anode 820B as deposited organic material 822B. Organic material 908 is a second color that is different from the color of organic material 904 (e.g., green).

As discussed with respect to FIGS. 9D-9F and 11, multiple masks may be used to manufacture display panels with different colored sub-pixels, in embodiments. To better illustrate the differences in masks for different colors of sub-pixels, FIGS. 12A-12C are described. FIG. 12A shows a block diagram 1200A of a mask 1202, in accordance with an example embodiment. FIG. 12B shows a block diagram 1200B of a mask 1206, according to an example embodiment. FIG. 12C shows a block diagram 1200C of a mask 1210, according to an example embodiment. FIGS. 12A-12C are described as follows with respect to FIGS. 9D-9F and 11.

Masks 1202, 1206, and 1210 are fine metal masks and include respective sub-pixel regions corresponding to sub-pixels of a particular color. For instance, mask 1202 comprises sub-pixel regions 1204A-1204D corresponding to sub-pixels of a first color (e.g., red), mask 1206 comprises sub-pixel regions 1208A-1208D corresponding to sub-pixels of a second color (e.g., green), and mask 1210 comprises sub-pixel regions 1212A-1212D corresponding to sub-pixels of a third color (e.g., blue). While only four sub-pixel regions are shown in each mask, embodiments of masks 1202, 1206, and 1210 may include many (e.g., tens, hundreds, thousands, and even greater) sub-pixel regions.

Masks 1202, 1206, and 1210 are used in a manufacturing process to control where organic material is deposited on a semiconductor material. In particular, masks 1202, 1206, and 1210 are used to deposit organic material corresponding to pixel pattern 500 of FIG. 5. For instance, mask 1202 is configured for use in the process described with respect to step 900D of FIG. 9D to deposit organic material of sub-pixels 502A-502D in sub-pixel regions 1204A-1204D on anodes of sub-pixels 502A-502D. Mask 1206 is configured for use in the process described with respect to step 900E of FIG. 9E to deposit organic material of sub-pixels 504A-504D in sub-pixel regions 1208A-1208D on anodes of sub-pixels 504A-504D. Mask 1210 is configured for use in the process described with respect to step 900F of FIG. 9F to deposit organic material of sub-pixels 506A-506D in sub-pixel regions 1212A-1212D on anodes of sub-pixels 506A-506D.

### IV. Example Image Processing Embodiments

As discussed herein, sub-pixels of display panels with under display cameras are designed to include static and dynamic corners such that scattering of light passing through the display panel is irregular (e.g., not periodic). This causes incident light captured by an under display camera to appear as noise in formed images. Embodiments of the present disclosure may utilize noise cancelling techniques to further remove visual artifacts from formed images. Noise can be removed in various ways, in embodiments. For instance, FIG. 13 shows a block diagram of a system 1300 for capturing and processing images, according to an example embodiment. System 1300 comprises a display panel 1304, a camera 1306, and a computing device 1302, each of which are examples of display panel 206, camera 208, and user device 202 as described with respect to FIGS. 2 and 3. Display panel 1304 comprises modified pixels 1318 (i.e., pixels that include modified sub-pixels (e.g., sub-pixels 216A-216n and/or sub-pixels 218A-218n, as described with respect to FIGS. 2 and 3)). Computing device 1302 comprises a display driver 1308 (which is an example of display driver 310 of FIG. 3 and controls modified pixels 1318 via drive signal 1320), an image processing system 1310, and memory 1312 (which is an example of memory 308 and/or memory 304 of FIG. 3). In accordance with an embodiment, image processing system 1310 comprises a processing circuit (e.g., a processor) that executes software and/or firmware to perform functions. Image processing system 1310 executes a machine learning (ML) model 1314. Memory 1312 stores image data 1316.

To better understand the operation of system 1300, system 1300 is described with respect to FIG. 14. FIG. 14 shows a flowchart of a process for processing an image, according to an example embodiment. System 1300 may operate according to flowchart 1400 in an embodiment. Note that not all steps of flowchart 1400 need be performed in all embodiments. Further structural and operational embodiments will be apparent to persons skilled in the relevant art(s) based on the following description of FIGS. 13 and 14.

Flowchart 1400 begins with step 1402. In step 1402, an image captured by a camera is received. For example, image processing system 1310 receives an image 1326 captured by camera 1306. Camera 1306 captures image 1326 by receiving light 1322 that passes through display panel 1304 as incident light 1324. Image 1326 is formed from incident light 1324. Image 1326 includes one or more visual artifacts caused by light 1322 scattering as it passes through modified pixels 1318 of display panel 1304. Modified pixels 1318 include sub-pixels with dynamic corners located in such a manner that sub-pixels of the same type are different in shape. This irregularity causes the portion of light 1322 that scatters to scatter irregularly (i.e., not periodically). Thus, incident light 1324 includes a scattered portion. The irregular scattering of light causes image 1326 to include a visual artifact with a PSF with (relatively) low energy lines. In other words, the visual artifact in image 1326 appears as visual noise (e.g., irregularities).

In step 1404, an ML model is used to filter a visual artifact from the image to generate a processed image. For example, image processing system 1310 utilizes ML model 1314 to filter the visual artifact from image 1326 to generate a processed image 1328. ML model 1314 is an ML model that is configured to filter visual noise from images. Since the configuration of modified pixels 1318 cause scattered light of incident light 1324 to appear as irregular visual noise, the effectiveness of ML model 1314 in filtering visual artifacts caused by scattered light is improved, thereby improving the quality in processed images generated by image processing system 1310. In accordance with an embodiment, image processing system 1310 stores processed image 1328 in memory 1312 as image data 1316 via storage signal 1330. Alternatively or additionally, image processing system 1310 transmits processed image 1328 to another component of computing device 1302 (e.g., display driver 1308, another component not shown in FIG. 13 for brevity) and/or another device external to computing device 1302 (e.g., over a network).

### V. Additional Example Sub-Pixel Design Embodiments

Example embodiments of sub-pixels and sub-pixel regions have been described with respect to FIGS. 4B, 5, 6A, 6B, and 12A-12C having irregular hexagonal. Embodiments of sub-pixel designs described herein are not limited to hexagon (or other six-sided) shapes. For instance, sub-pixels may have any number of sides and/or corners. A regular configuration of a sub-pixel may be shape of a fan, a dumbbell, a pear, a quadrilateral, a pentagon, a quasi-rectangle, a rounded rectangle, a trapezoid, a quasi-trapezoid, a rounded trapezoid, star, a heart, and/or in any other type of shape suitable for a sub-pixel in a display panel, as would be understood by a person ordinarily skilled in the relevant art(s) having benefit of this disclosure. Different types of sub-pixels within a pixel unit may correspond to the same shape in a regular configuration (e.g., all sub-pixels in a pixel unit are six sided and correspond to a hexagon shape in a regular configuration) or different shapes in respective configurations (e.g., a first and second sub-pixel in a pixel unit are four sided and correspond to a square shape in a regular configuration while a third sub-pixel in the pixel unit are four sided and correspond to a rectangle shape in a regular configuration). One or more edges of a sub-pixel may be curved. Embodiments of sub-pixels may have regular corners, chamfered corners, filleted corners, or any other type of corners (e.g., irregular corners due to manufacturing tolerances). In the case of irregular corners (e.g., chamfered corners, filleted corners, and/or the like), dynamic and static corners in accordance with an embodiment represent an approximate center of the irregular corner. Alternatively, multiple static and dynamic corners are used for a single irregular corner.

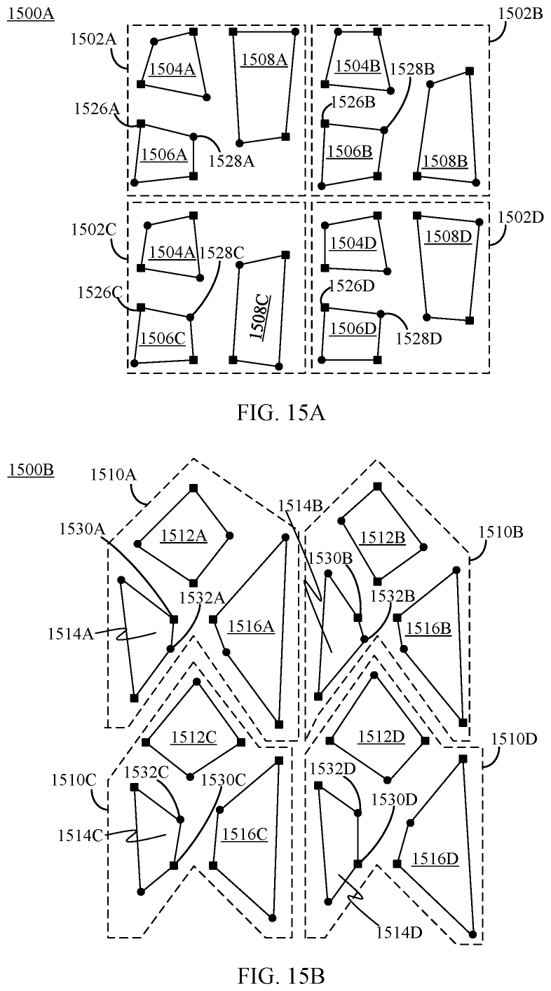

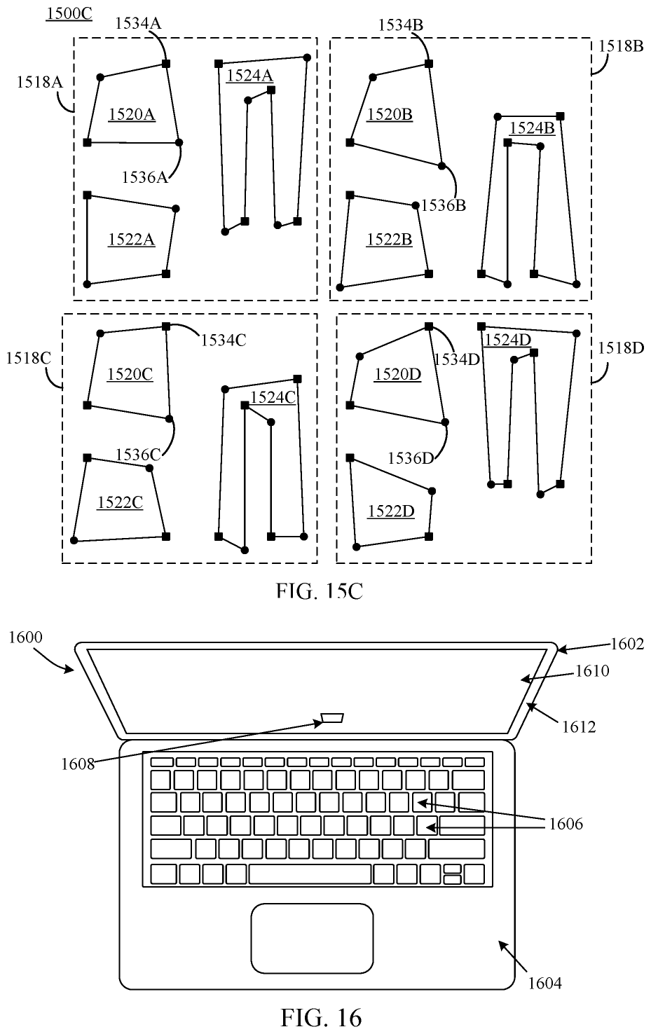

As described herein, sub-pixels may be designed in a variety of shapes and patterns. For instance, sub-pixels may be configured in a “stripe” pixel pattern. For example, FIG. 15A shows a block diagram of a pixel pattern 1500A, according to another example embodiment. Pixel pattern 1500A represents a close-up view of four pixels of display portion 212 of FIG. 2 and/or display portion 404 of FIG. 4A. Pixel pattern 1500A includes pixels 1502A, 1502B, 1502C, and 150D. Pixel 1502A includes sub-pixels 1504A, 1506A, and 1508A. Pixel 1502B includes sub-pixels 1504B, 1506B, and 1508B. Pixel 1502C includes sub-pixels 1504C, 1506C, and 1508C. Pixel 1502D includes sub-pixels 1504D, 1506D, and 1508D. Sub-pixels 1504A-1504D are a first type of sub-pixel and correspond to a square shape in a regular configuration. Sub-pixels 1506A-1506D are a second type of sub-pixel and correspond to a square shape in a regular configuration. Sub-pixels 1508A-1508D are a third type of sub-pixel and correspond to a rectangle shape in a regular configuration. In accordance with an embodiment, sub-pixels 1504A-1504D emit a first color of light (e.g., red), sub-pixels 1506A-1506D emit a second color of light (e.g., green), and sub-pixels 1508A-1508D emit a third color of light (e.g., blue).

As shown in FIG. 15A, each sub-pixel of pixels 1502A-1502D includes two static corners and two dynamic corners. Static corners of sub-pixels 1504A-1504D are at a same position relative to a respective sub-pixel center and static corners of sub-pixels 1506A-1506D are at a same position relative to a respective sub-pixel center. For instance, static corner 1526A is at a same position relative to a sub-pixel center of sub-pixel 1506A as static corner 1526B relative to a sub-pixel center of sub-pixel 1506B, as static corner 1526C relative to a sub-pixel center of sub-pixel 1506C, and as static corner 1526D relative to a sub-pixel center of sub-pixel 1506D.

In some embodiments, sub-pixels may shift in a pattern with respect to a pixel unit's center. For instance, as shown in FIG. 15A, the positions of sub-pixels 1508A-1508D shift with respect to a center of respective pixels 1502A-1502D such that a center of every other sub-pixel of 1508A-1508D is in the same position with respect to the respective pixel's center. For instance, sub-pixel 1508A is in the same position relative to a center of pixel 1502A as sub-pixel 1508D is relative to a center of pixel 1502D. Sub-pixel 1508B is in the same position relative to a center of pixel 1502B as sub-pixel 1508C is relative to a center of pixel 1502C.

The positions of dynamic corners of sub-pixels 1504A-1504D, 1506A-1506D, and 1508A-1508D are located such that sub-pixels 1504A-1504D are different shapes from each other, sub-pixels 1506A-1506D are different shapes from each other, and sub-pixels 1508A-1508D are different shapes from each other. For instance, the positions of dynamic corners 1528A-1528D are located such that respective shapes of sub-pixels 1506A-1506D are different from each other.

As described herein, sub-pixels may be designed in a variety of shapes. For example, FIG. 15B shows a block diagram of a pixel pattern 1500B, according to another example embodiment. Pixel pattern 1500B represents a close-up view of four pixels of display portion 212 of FIG. 2 and/or display portion 404 of FIG. 4A. Pixel pattern 1500B includes pixels 1510A-1510D. Pixel 1510A includes sub-pixels 1512A, 1514A, and 1516A, pixel 1510B includes sub-pixels 1512B, 1514B, and 1516B, pixel 1510C includes sub-pixels 1512C, 1514C, and 1516C, and pixel 1510D includes sub-pixels 1512D, 1514D, and 1516D. Sub-pixels 1512A-1512D are a first type of sub-pixel and correspond to a square shape in a regular configuration. Sub-pixels 1514A-1514D are a second type of sub-pixel and correspond to a trapezoid shape in a regular configuration. Sub-pixels 1516A-1516D are a third type of sub-pixel and correspond to a trapezoid shape in a regular configuration. In accordance with an embodiment, sub-pixels 1512A-1512D emit a first color of light (e.g., blue), sub-pixels 1514A-1514D emit a second color of light (e.g., red), and sub-pixels 1516A-1516D emit a third color of light (e.g., green).

As shown in FIG. 15B, each sub-pixel of pixels 510A-510D includes two static corners and two dynamic corners. Static corners of sub-pixels 1512A and 1512B are at a same position relative to a respective sub-pixel center, static corners of sub-pixels 1512C and 1512D are at a same position relative to a respective sub-pixel center, static corners of sub-pixels 1514A and 1514B are at a same position relative to a respective sub-pixel center, static corners of sub-pixels 1514C and 1514D are at a same position relative to a respective sub-pixel center, and static corners of sub-pixels 1516A and 1516B are at a same position relative to a respective sub-pixel center, static corners of sub-pixels 1516C and 1516D are at a same position relative to a respective sub-pixel center. For instance, static corner 1530A is at a same position relative to a sub-pixel center of sub-pixel 1514A as static corner 1530B is relative to a sub-pixel center of sub-pixel 1514B, and static corner 1530C is at a same relative to a sub-pixel center of sub-pixel 1514C as static corner 530D is relative to a sub-pixel center of sub-pixel 1514D.

The positions of dynamic corners of sub-pixels 1512A-1512D, 1514A-1514D, and 1516A-1516D are located such that sub-pixels 1512A-1512D are different shapes from each other, sub-pixels 1514A-1514D are different shapes from each other, and sub-pixels 1516A-1516D are different shapes from each other. For instance, the positions of dynamic corners 1532A and 1532B are located such that the shape of sub-pixel 1514A is different from the shape of sub-pixel 1514B, and the positions of dynamic corners 1532C and 1532D are located such that the shape of sub-pixel 1514C is different from the shape of sub-pixel 1514D.

In some embodiments, which corners of a first set of sub-pixels are dynamic corners and which corners of the first set of sub-pixels are static corners is different from a second set of sub-pixels in a pixel pattern. For instance, as shown in FIG. 15B, the static corners and dynamic corners of sub-pixels of pixels 1510A and 1510B (e.g., a “first set of sub-pixels”) are different from the static corners and dynamic corners of sub-pixels of pixels 1510C and 1510D (e.g., a “second set of sub-pixels”). By using different static corners and dynamic corners for different sets of sub-pixels, the angles of edges of adjacent pixels can be adjusted irregularly with a PDL gap near a minimum PDL gap threshold and with pixel areas within (or above) a predetermined range. For instance, since the corners of sub-pixels of pixels 1510A and 1510B alternate from the corners of sub-pixels of pixels 1510C and 1510D, angles between edges of adjacent pixels are adjusted in an irregular manner that reduces high energy lines of scattered light that passes through pixel pattern 1500B while maintaining at least a minimum PDL gap between adjacent pixels and maintaining emissive areas of adjacent sub-pixels within (or above) a predetermined range.

As described herein, sub-pixels may be designed in a variety of shapes and patterns. Furthermore, sub-pixels of one type may have a different number of static and/or dynamic corners than sub-pixels of another type within the same pixel. For example, FIG. 15C shows a block diagram of a pixel pattern 1500C, according to another example embodiment. Pixel pattern 1500C represents a close-up view of four pixels of display portion 212 of FIG. 2 and/or display portion 404 of FIG. 4A. Pixel pattern 1500C includes pixels 1518A-1518D. Pixel 1518A includes sub-pixels 1520A, 1522A, and 1524A, pixel 1518B includes sub-pixels 1520B, 1522B, and 1524B, pixel 1518C includes sub-pixels 1520C, 1522C, and 1524C, and pixel 1518D includes sub-pixels 1520D, 1522D, and 1524D. Sub-pixels 1520A-1520D are a first type of sub-pixel and correspond to a square shape in a regular configuration. Sub-pixels 1522A-1522D are a second type of sub-pixel and correspond to a square shape in a regular configuration. Sub-pixels 1524A-1524D are a third type of sub-pixel and correspond to a rectangle shape with a channel in a regular configuration. In accordance with an embodiment, sub-pixels 1520A-1520D emit a first color of light (e.g., red), sub-pixels 1522A-1522D emit a second color of light (e.g., green), and sub-pixels 1524A-1524D emit a third color of light (e.g., blue). In FIG. 15C, the positions of centers of sub-pixels 1524A-1524D shift relative to a center of respective pixels 1518A-1518D in a similar manner as sub-pixels 1508A-1508D of FIG. 15A.

As shown in FIG. 15C, each of sub-pixels 1520A-1520D and 1522A-1522D include two respective static corners and two respective dynamic corners. Static corners of sub-pixels 1520A-1520D are at a same position relative to a respective sub-pixel center and static corners of sub-pixels 1522A-1522D are at a same position relative to a respective sub-pixel center. For instance, static corner 1534A is at a same position relative to a sub-pixel center of sub-pixel 1520A as static corner 1534B relative to a sub-pixel center of sub-pixel 1520B, as static corner 1534C relative to a sub-pixel center of sub-pixel 1520C, and as static corner 1534D relative to a sub-pixel center of sub-pixel 1520D. The positions of dynamic corners of sub-pixels 1520A-1520D and 1522A-1522D are located such that sub-pixels 1520A-1520D are different shapes from each other and sub-pixels 1522A-1522D are different shapes from each other. For instance, the positions of dynamic corners 1536A-1536D are located such that the respective shapes of sub-pixels 1520A-1520D are different from each other.

As shown in FIG. 15C, sub-pixels 1524A-1524D correspond to rectangle shapes in a regular configuration but with channels, resulting in a “horseshoe” shape. The channel prevents separation of layers during the manufacturing process of sub-pixels 1524A-1524D (e.g., due to gassing off caused by the large size of the area of sub-pixels 1524A-1524D. In accordance with an embodiment, and as shown in FIG. 15C, the channels of sub-pixels 1524A-1524D include static and dynamic corner such that angles of edges of the channels are in an irregular pattern. In this context, each of sub-pixels 1524A-1524D include four respective static corners and four respective dynamic corners. Static corners of sub-pixels 1524A-1524D are at a same position relative to a respective sub-pixel center. The positions of dynamic corners of sub-pixels 1524A-1524D are located such that sub-pixels 1524A-1524D are different shapes from each other. In some embodiments, the positions of dynamic corners of channels of sub-pixels 1524A-1524D are located such that a minimum channel width is above a minimum channel width threshold. Alternatively or additionally, dynamic corners of sub-pixels 1524A-1524D (including the dynamic corners of the respective channels) are located such that a minimum sub-pixel width is above a minimum sub-pixel width threshold. In an alternative embodiment, the positions of corners of channels of sub-pixels 1524A-1524D are static relative to respective sub-pixel centers. In another alternative embodiment, each corner of a channel of sub-pixels 1524A-1524D is a dynamic corner (e.g., in a manner such that only outer corners of sub-pixels 1524A-1524D include static corners).

Thus, example alternative embodiments of pixel patterns have been described with respect to FIGS. 15A-15C. In each of these cases, the positions of dynamic corners of sub-pixels of the same type are located such that the shapes of sub-pixels of the same type are different from each other. By locating positions of dynamic corners of sub-pixels in this manner, the angles of edges of adjacent sub-pixels with respect to one another are irregular (e.g., not periodic). The irregularity of these angles causes the PSF of light passing through a display portion including the pixels to have lower energy lines, thereby reducing or removing visual artifacts that appear in images taken by an under display camera that captures light passing through the display portion. Furthermore, the irregularity of scattering of light passing through such a display portion causes the scattered light captured by an under display camera to appear as (e.g., visual) noise. As discussed with respect to FIGS. 13 and 14 (and elsewhere herein), causing scattered light to appear as noise improves an image processing system's capability to filter visual artifacts caused by the scattered light (e.g., by using a ML model configured to filter visual noise from captured images). This further improves the image quality of a processed image generated by a display device with an under display camera.

### VI. Example Embodiments of Display Devices and Manufacturing of Display Panels

In various embodiments, camera 208 of FIG. 2 is physically a part of user device 202 (e.g., a hardware component that is installed and/or integral to a housing thereof) comprising a display panel with modified sub-pixels. For instance, FIG. 16 shows a computing device 1600 that includes a display panel with modified sub-pixels, according to an example embodiment. The configuration of computing device 1600 is only illustrative, and other configurations (e.g., tablets, desktops, etc.) are also possible for implementing the disclosed techniques.

FIG. 16 depicts computing device 1600 in an open orientation. Computing device 1600 comprises a display 1602 and a base 1604 that are movably attached to each other (e.g., rotatable with respect to each other) via a hinge point (not shown in FIG. 16 for illustrative brevity). Base 1604 comprises a keyboard with keyboard keys 1606. Display 1602 comprises a display panel 1610 (which is an example of display panel 206 of FIGS. 2 and 3 and/or display panel 402 of FIG. 4A), an under display camera area 1608 (which is an example of sub-portion 408 of FIG. 4A), and a display bezel 1612. In examples, display bezel 1612 comprises a portion of display 1602 that surrounds a periphery of display panel 1610 and is in a plane that is parallel to a plane of display panel 1610.

Under display camera area 1608 represents the position of an under display camera (e.g., camera 208 of FIG. 2) located behind (or otherwise underneath) display panel 1610. In some embodiments, under display camera area 1608 is larger than the area of the camera, thus enabling the camera to capture incident light that passes through display portion 404 at an angle relative to the position of the camera (e.g., at a field of view wider than the width of the camera lens). In accordance with an embodiment, pixels of display panel 1610 in under display camera area 1608 include sub-pixels with dynamic and static corners as described elsewhere herein. By designing sub-pixels of display panel 1610 in under display camera area 1608 to include dynamic corners with positions located such that the sub-pixels are different shapes in the various manners described herein, the angles of edges of adjacent sub-pixels with respect to one another are irregular (e.g., not periodic). The irregularity of these angles causes the PSF of light passing through under display camera area 1608 to have lower energy lines, thereby reducing or removing visual artifacts that appear in images taken by the camera. Furthermore, the irregularity of scattering of light passing through under display camera area 1608 causes scattered light captured by an under display camera to appear as noise. As discussed with respect to FIGS. 13 and 14 (and elsewhere herein), by causing scattered light to appear as noise, an image processing system's capability to filter visual artifacts caused by the scattered light is improved. This further improves the image quality of a processed image generated by such an image processing system and an under display camera.

Although not illustrated herein, computing device 1600 can contain any more or less than the components shown in FIG. 16. In some examples, computing device 1600 contains multiple under display cameras. In some examples, computing device 1600 includes other sensors (e.g., optical sensors other than under display cameras (e.g., optical sensors embedded in the keyboard area of base 1604, optical sensors embedded in bezel 1612, etc.), and/or any other type of sensor). Furthermore, the under display camera area of computing device 1600 is arrangeable in any location of display panel 1610 and is not limited to the illustrative placement shown in FIG. 16.

### VII. Example Computer System Implementation

As noted herein, the embodiments described, along with any circuits, components and/or subcomponents thereof, as well as the flowcharts/flow diagrams described herein, including portions thereof, and/or other embodiments, may be implemented in hardware, or hardware with any combination of software and/or firmware, including being implemented as computer program code configured to be executed in one or more processors and stored in a computer readable storage medium, or being implemented as hardware logic/electrical circuitry, such as being implemented together in a system-on-chip (SoC), a field programmable gate array (FPGA), and/or an application specific integrated circuit (ASIC). A SoC may include an integrated circuit chip that includes one or more of a processor (e.g., a microcontroller, microprocessor, digital signal processor (DSP), etc.), memory, one or more communication interfaces, and/or further circuits and/or embedded firmware to perform its functions.

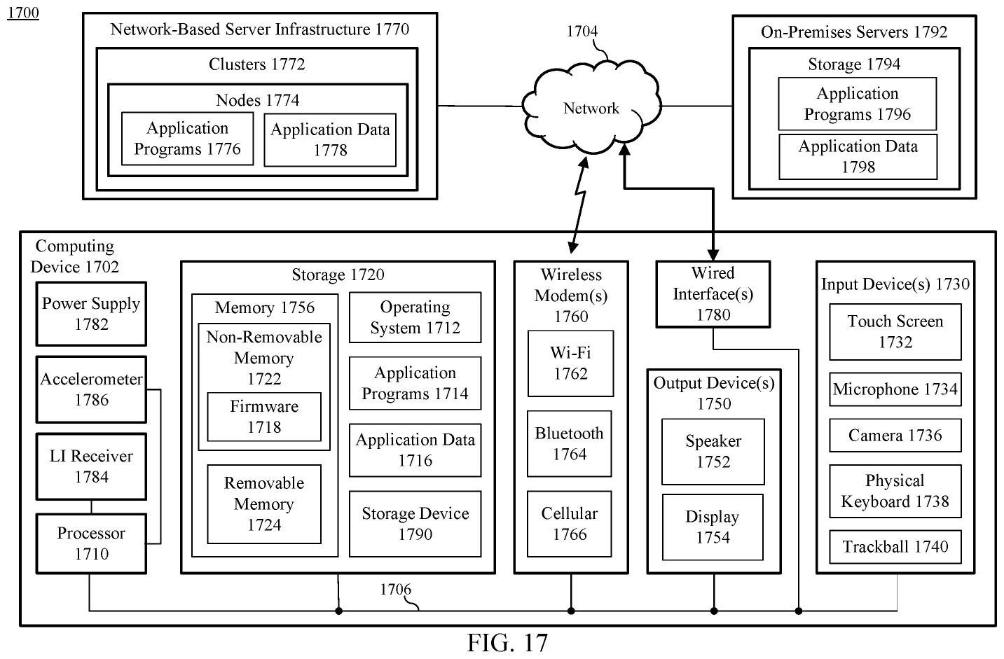

Embodiments disclosed herein may be implemented in one or more computing devices that may be mobile (a mobile device) and/or stationary (a stationary device) and may include any combination of the features of such mobile and stationary computing devices. Examples of computing devices in which embodiments may be implemented are described as follows with respect to FIG. 17. FIG. 17 shows a block diagram of an exemplary computing environment 1700 that includes a computing device 1702. Computing device 1702 is an example of user device 202 of FIGS. 1 and 2, display panel 702, camera 704, and/or point source 716 of FIG. 7, display panel 802, camera 804, and/or display driver 806 of FIG. 8, computing device 1302, display panel 1304, and/or camera 1306 of FIG. 13, and/or computing device 1600 of FIG. 16, each of which may include one or more of the components of computing device 1702. In some embodiments, computing device 1702 is communicatively coupled with devices (not shown in FIG. 17) external to computing environment 1700 via network 1704. Network 1704 comprises one or more networks such as local area networks (LANs), wide area networks (WANs), enterprise networks, the Internet, etc., and may include one or more wired and/or wireless portions. Network 1704 may additionally or alternatively include a cellular network for cellular communications. Computing device 1702 is described in detail as follows.

Computing device 1702 can be any of a variety of types of computing devices. For example, computing device 1702 may be a mobile computing device such as a handheld computer (e.g., a personal digital assistant (PDA)), a laptop computer, a tablet computer (such as an Apple iPad™), a hybrid device, a notebook computer (e.g., a Google Chromebook™ by Google LLC), a netbook, a mobile phone (e.g., a cell phone, a smart phone such as an Apple® iPhone® by Apple Inc., a phone implementing the Google® Android™ operating system, etc.), a wearable computing device (e.g., a head-mounted augmented reality and/or virtual reality device including smart glasses such as Google® Glass™, Oculus Rift® of Facebook Technologies, LLC, etc.), or other type of mobile computing device. Computing device 1702 may alternatively be a stationary computing device such as a desktop computer, a personal computer (PC), a stationary server device, a minicomputer, a mainframe, a supercomputer, etc.

As shown in FIG. 17, computing device 1702 includes a variety of hardware and software components, including a processor 1710, a storage 1720, one or more input devices 1730, one or more output devices 1750, one or more wireless modems 1760, one or more wired interfaces 1780, a power supply 1782, a location information (LI) receiver 1784, and an accelerometer 1786. Storage 1720 includes memory 1756, which includes non-removable memory 1722 and removable memory 1724, and a storage device 1790. Storage 1720 also stores operating system 1712, application programs 1714, and application data 1716. Wireless modem(s) 1760 include a Wi-Fi modem 1762, a Bluetooth modem 1764, and a cellular modem 1766. Output device(s) 1750 includes a speaker 1752 and a display 1754. Display 1754 is an example of display device 204 as described with respect to FIGS. 2 and 3, display panel 402 as described with respect to FIG. 4A, display panel 702 as described with respect to FIG. 7A, display panel 802 as described with respect to FIG. 8, display panel 1304 as described with respect to FIG. 13, and/or display 1602 as described with respect to FIG. 16. Input device(s) 1730 includes a touch screen 1732, a microphone 1734, a camera 1736, a physical keyboard 1738, and a trackball 1740. Not all components of computing device 1702 shown in FIG. 17 are present in all embodiments, additional components not shown may be present, and any combination of the components may be present in a particular embodiment. These components of computing device 1702 are described as follows.

A single processor 1710 (e.g., central processing unit (CPU), microcontroller, a microprocessor, signal processor, ASIC (application specific integrated circuit), and/or other physical hardware processor circuit) or multiple processors 1710 may be present in computing device 1702 for performing such tasks as program execution, signal coding, data processing, input/output processing, power control, and/or other functions. Processor 1710 may be a single-core or multi-core processor, and each processor core may be single-threaded or multithreaded (to provide multiple threads of execution concurrently). Processor 1710 is configured to execute program code stored in a computer readable medium, such as program code of operating system 1712 and application programs 1714 stored in storage 1720. Operating system 1712 controls the allocation and usage of the components of computing device 1702 and provides support for one or more application programs 1714 (also referred to as “applications” or “apps”). Application programs 1714 may include common computing applications (e.g., e-mail applications, calendars, contact managers, web browsers, messaging applications), further computing applications (e.g., word processing applications, mapping applications, media player applications, productivity suite applications), one or more machine learning (ML) models (e.g., ML model 1314 of FIG. 13), as well as applications related to the embodiments disclosed elsewhere herein.

Any component in computing device 1702 can communicate with any other component according to function, although not all connections are shown for ease of illustration. For instance, as shown in FIG. 17, bus 1706 is a multiple signal line communication medium (e.g., conductive traces in silicon, metal traces along a motherboard, wires, etc.) that may be present to communicatively couple processor 1710 to various other components of computing device 1702, although in other embodiments, an alternative bus, further buses, and/or one or more individual signal lines may be present to communicatively couple components. Bus 1706 represents one or more of any of several types of bus structures, including a memory bus or memory controller, a peripheral bus, an accelerated graphics port, and a processor or local bus using any of a variety of bus architectures.

Storage 1720 is physical storage that includes one or both of memory 1756 and storage device 1790, which store operating system 1712, application programs 1714, and application data 1716 according to any distribution. Non-removable memory 1722 includes one or more of RAM (random access memory), ROM (read only memory), flash memory, a solid-state drive (SSD), a hard disk drive (e.g., a disk drive for reading from and writing to a hard disk), and/or other physical memory device type. Non-removable memory 1722 may include main memory and may be separate from or fabricated in a same integrated circuit as processor 1710. As shown in FIG. 17, non-removable memory 1722 stores firmware 1718, which may be present to provide low-level control of hardware. Examples of firmware 1718 include BIOS (Basic Input/Output System, such as on personal computers) and boot firmware (e.g., on smart phones). Removable memory 1724 may be inserted into a receptacle of or otherwise coupled to computing device 1702 and can be removed by a user from computing device 1702. Removable memory 1724 can include any suitable removable memory device type, including an SD (Secure Digital) card, a Subscriber Identity Module (SIM) card, which is well known in GSM (Global System for Mobile Communications) communication systems, and/or other removable physical memory device type. One or more of storage device 1790 may be present that are internal and/or external to a housing of computing device 1702 and may or may not be removable. Examples of storage device 1790 include a hard disk drive, a SSD, a thumb drive (e.g., a USB (Universal Serial Bus) flash drive), or other physical storage devices.

One or more programs may be stored in storage 1720. Such programs include operating system 1712, one or more application programs 1714, and other program modules and program data. Examples of such application programs may include, for example, computer program logic (e.g., computer program code/instructions) for implementing one or more of display driver 310, display controller 320, camera controller 322, image processing logic 324, display driver 806, display driver 1308, image processing system 1310, and/or ML model 1314, along with any components and/or subcomponents thereof, as well as the flowcharts/flow diagrams (e.g., flowcharts 1000, 1100, and/or 1400) described herein, including portions thereof, and/or further examples described herein.

Storage 1720 also stores data used and/or generated by operating system 1712 and application programs 1714 as application data 1716. Examples of application data 1716 include web pages, text, images, tables, sound files, video data, and other data, which may also be sent to and/or received from one or more network servers or other devices via one or more wired or wireless networks. Storage 1720 can be used to store further data including a subscriber identifier, such as an International Mobile Subscriber Identity (IMSI), and an equipment identifier, such as an International Mobile Equipment Identifier (IMEI). Such identifiers can be transmitted to a network server to identify users and equipment.

A user may enter commands and information into computing device 1702 through one or more input devices 1730 and may receive information from computing device 1702 through one or more output devices 1750. Input device(s) 1730 may include one or more of touch screen 1732, microphone 1734, camera 1736, physical keyboard 1738 and/or trackball 1740 and output device(s) 1750 may include one or more of speaker 1752 and display 1754. Each of input device(s) 1730 and output device(s) 1750 may be integral to computing device 1702 (e.g., built into a housing of computing device 1702) or external to computing device 1702 (e.g., communicatively coupled wired or wirelessly to computing device 1702 via wired interface(s) 1780 and/or wireless modem(s) 1760). Further input devices 1730 (not shown) can include a Natural User Interface (NUI), a pointing device (computer mouse), a joystick, a video game controller, a scanner, a touch pad, a stylus pen, a voice recognition system to receive voice input, a gesture recognition system to receive gesture input, or the like. Other possible output devices (not shown) can include piezoelectric or other haptic output devices. Some devices can serve more than one input/output function. For instance, display 1754 may display information, as well as operating as touch screen 1732 by receiving user commands and/or other information (e.g., by touch, finger gestures, virtual keyboard, etc.) as a user interface. Any number of each type of input device(s) 1730 and output device(s) 1750 may be present, including multiple microphones 1734, multiple cameras 1736, multiple speakers 1752, and/or multiple displays 1754.

One or more wireless modems 1760 can be coupled to antenna(s) (not shown) of computing device 1702 and can support two-way communications between processor 1710 and devices external to computing device 1702 through network 1704, as would be understood to persons skilled in the relevant art(s). Wireless modem 1760 is shown generically and can include a cellular modem 1766 for communicating with one or more cellular networks, such as a GSM network for data and voice communications within a single cellular network, between cellular networks, or between the mobile device and a public switched telephone network (PSTN). Wireless modem 1760 may also or alternatively include other radio-based modem types, such as a Bluetooth modem 1764 (also referred to as a “Bluetooth device”) and/or Wi-Fi 1762 modem (also referred to as an “wireless adaptor”). Wi-Fi modem 1762 is configured to communicate with an access point or other remote Wi-Fi-capable device according to one or more of the wireless network protocols based on the IEEE (Institute of Electrical and Electronics Engineers) 802.11 family of standards, commonly used for local area networking of devices and Internet access. Bluetooth modem 1764 is configured to communicate with another Bluetooth-capable device according to the Bluetooth short-range wireless technology standard(s) such as IEEE 802.15.1 and/or managed by the Bluetooth Special Interest Group (SIG).

Computing device 1702 can further include power supply 1782, LI receiver 1784, accelerometer 1786, and/or one or more wired interfaces 1780. Example wired interfaces 1780 include a USB port, IEEE 1394 (FireWire) port, a RS-232 port, an HDMI (High-Definition Multimedia Interface) port (e.g., for connection to an external display), a DisplayPort port (e.g., for connection to an external display), an audio port, an Ethernet port, and/or an Apple® Lightning® port, the purposes and functions of each of which are well known to persons skilled in the relevant art(s). Wired interface(s) 1780 of computing device 1702 provide for wired connections between computing device 1702 and network 1704, or between computing device 1702 and one or more devices/peripherals when such devices/peripherals are external to computing device 1702 (e.g., a pointing device, display 1754, speaker 1752, camera 1736, physical keyboard 1738, etc.). Power supply 1782 is configured to supply power to each of the components of computing device 1702 and may receive power from a battery internal to computing device 1702, and/or from a power cord plugged into a power port of computing device 1702 (e.g., a USB port, an A/C power port). LI receiver 1784 may be used for location determination of computing device 1702 and may include a satellite navigation receiver such as a Global Positioning System (GPS) receiver or may include other type of location determiner configured to determine location of computing device 1702 based on received information (e.g., using cell tower triangulation, etc.). Accelerometer 1786 may be present to determine an orientation of computing device 1702.

Note that the illustrated components of computing device 1702 are not required or all-inclusive, and fewer or greater numbers of components may be present as would be recognized by one skilled in the art. For example, computing device 1702 may also include one or more of a gyroscope, barometer, proximity sensor, ambient light sensor, digital compass, etc. Processor 1710 and memory 1756 may be co-located in a same semiconductor device package, such as being included together in an integrated circuit chip, FPGA, or system-on-chip (SOC), optionally along with further components of computing device 1702.

In embodiments, computing device 1702 is configured to implement any of the above-described features of flowcharts herein. Computer program logic for performing any of the operations, steps, and/or functions described herein may be stored in storage 1720 and executed by processor 1710.

In some embodiments, server infrastructure 1770 may be present in computing environment 1700 and may be communicatively coupled with computing device 1702 via network 1704. Server infrastructure 1770, when present, may be a network-accessible server set (e.g., a cloud computing platform). As shown in FIG. 17, server infrastructure 1770 includes clusters 1772. Each of clusters 1772 may comprise a group of one or more compute nodes and/or a group of one or more storage nodes. For example, as shown in FIG. 17, cluster 1772 includes nodes 1774. Each of nodes 1774 is accessible via network 1704 (e.g., in a “cloud computing platform” or “cloud-based” embodiment) to build, deploy, and manage applications and services. Any of nodes 1774 may be a storage node that comprises a plurality of physical storage disks, SSDs, and/or other physical storage devices that are accessible via network 1704 and are configured to store data associated with the applications and services managed by nodes 1774. For example, as shown in FIG. 17, nodes 1774 may store application data 1778.

Each of nodes 1774 may, as a compute node, comprise one or more server computers, server systems, and/or computing devices. For instance, a node 1774 may include one or more of the components of computing device 1702 disclosed herein. Each of nodes 1774 may be configured to execute one or more software applications (or “applications”) and/or services and/or manage hardware resources (e.g., processors, memory, etc.), which may be utilized by users (e.g., customers) of the network-accessible server set. For example, as shown in FIG. 17, nodes 1774 may operate application programs 1776. In an implementation, a node of nodes 1774 may operate or comprise one or more virtual machines, with each virtual machine emulating a system architecture (e.g., an operating system), in an isolated manner, upon which applications such as application programs 1776 may be executed.

In an embodiment, one or more of clusters 1772 may be co-located (e.g., housed in one or more nearby buildings with associated components such as backup power supplies, redundant data communications, environmental controls, etc.) to form a datacenter, or may be arranged in other manners. Accordingly, in an embodiment, one or more of clusters 1772 may be a datacenter in a distributed collection of datacenters. In embodiments, exemplary computing environment 1700 comprises part of a cloud-based platform such as Amazon Web Services® of Amazon Web Services, Inc., or Google Cloud Platform™ of Google LLC, although these are only examples and are not intended to be limiting.

In an embodiment, computing device 1702 may access application programs 1776 for execution in any manner, such as by a client application and/or a browser at computing device 1702. Example browsers include Microsoft Edge® by Microsoft Corp. of Redmond, Washington, Mozilla Firefox®, by Mozilla Corp. of Mountain View, California, Safari®, by Apple Inc. of Cupertino, California, and Google® Chrome by Google LLC of Mountain View, California.

For purposes of network (e.g., cloud) backup and data security, computing device 1702 may additionally and/or alternatively synchronize copies of application programs 1714 and/or application data 1716 to be stored at network-based server infrastructure 1770 as application programs 1776 and/or application data 1778. For instance, operating system 1712 and/or application programs 1714 may include a file hosting service client, such as Microsoft® OneDrive® by Microsoft Corporation, Amazon Simple Storage Service (Amazon S3)® by Amazon Web Services, Inc., Dropbox® by Dropbox, Inc., Google Drive™ by Google LLC, etc., configured to synchronize applications and/or data stored in storage 1720 at network-based server infrastructure 1770.

In some embodiments, on-premises servers 1792 may be present in computing environment 1700 and may be communicatively coupled with computing device 1702 via network 1704. On-premises servers 1792, when present, are hosted within an organization's infrastructure and, in many cases, physically onsite of a facility of that organization. On-premises servers 1792 are controlled, administered, and maintained by IT (Information Technology) personnel of the organization or an IT partner to the organization. Application data 1798 may be shared by on-premises servers 1792 between computing devices of the organization, including computing device 1702 (when part of an organization) through a local network of the organization, and/or through further networks accessible to the organization (including the Internet). Furthermore, on-premises servers 1792 may serve applications such as application programs 1796 to the computing devices of the organization, including computing device 1702. Accordingly, on-premises servers 1792 may include storage 1794 (which includes one or more physical storage devices such as storage disks and/or SSDs) for storage of application programs 1796 and application data 1798 and may include one or more processors for execution of application programs 1796. Still further, computing device 1702 may be configured to synchronize copies of application programs 1714 and/or application data 1716 for backup storage at on-premises servers 1792 as application programs 1796 and/or application data 1798.

Embodiments described herein may be implemented in one or more of computing device 1702, network-based server infrastructure 1770, and on-premises servers 1792. For example, in some embodiments, computing device 1702 may be used to implement systems, clients, or devices, or components/subcomponents thereof, disclosed elsewhere herein. In other embodiments, a combination of computing device 1702, network-based server infrastructure 1770, and/or on-premises servers 1792 may be used to implement the systems, clients, or devices, or components/subcomponents thereof, disclosed elsewhere herein.

As used herein, the terms “computer program medium,” “computer-readable medium,” and “computer-readable storage medium,” etc., are used to refer to physical hardware media. Examples of such physical hardware media include any hard disk, optical disk, SSD, other physical hardware media such as RAMs, ROMs, flash memory, digital video disks, zip disks, MEMs (microelectronic machine) memory, nanotechnology-based storage devices, and further types of physical/tangible hardware storage media of storage 1720. Such computer-readable media and/or storage media are distinguished from and non-overlapping with communication media and propagating signals (do not include communication media and propagating signals). Communication media embodies computer-readable instructions, data structures, program modules or other data in a modulated data signal such as a carrier wave. The term “modulated data signal” means a signal that has one or more of its characteristics set or changed in such a manner as to encode information in the signal. By way of example, and not limitation, communication media includes wireless media such as acoustic, RF, infrared and other wireless media, as well as wired media. Embodiments are also directed to such communication media that are separate and non-overlapping with embodiments directed to computer-readable storage media.

As noted above, computer programs and modules (including application programs 1714) may be stored in storage 1720. Such computer programs may also be received via wired interface(s) 1780 and/or wireless modem(s) 1760 over network 1704. Such computer programs, when executed or loaded by an application, enable computing device 1702 to implement features of embodiments discussed herein. Accordingly, such computer programs represent controllers of the computing device 1702.

Embodiments are also directed to computer program products comprising computer code or instructions stored on any computer-readable medium or computer-readable storage medium. Such computer program products include the physical storage of storage 1720 as well as further physical storage types.

### VIII. Additional Exemplary Embodiments

A display device is described herein. The display device comprises a display panel comprising a first display portion. The first display portion comprises a first sub-pixel and a second sub-pixel. Each of the first and second sub-pixels includes a respective first static corner at a same position relative to a respective sub-pixel center, and a respective first dynamic corner. The position of each first dynamic corner is located such that a shape of the first sub-pixel is different from the shape of the second sub-pixel.

In an implementation of the foregoing display device, the first display portion further comprises a pixel. The pixel comprises the first sub-pixel and a third sub-pixel. The third sub-pixel includes a second static corner and a second dynamic corner. The first sub-pixel is adjacent to the third sub-pixel. The position of the first dynamic corner of the first sub-pixel is located to decrease an interior angle relative to the interior angle of the first dynamic corner in a regular polygon configuration of the first sub-pixel. The position of the second dynamic corner of the third sub-pixel is located to increase an interior angle of the second dynamic corner in a regular polygon configuration of the third sub-pixel.

In an implementation of the foregoing display device, the position of each first dynamic corner is located to decrease an interior angle relative to the interior angle of the respective first dynamic corner in a regular polygon configuration of the respective sub-pixel.

In an implementation of the foregoing display device, each of the first and second sub-pixels further include a respective second dynamic corner. The position of each first dynamic corner and the position of each second dynamic corner are located such that respective areas of the first and second sub-pixels are within a predetermined range.

In an implementation of the foregoing display device, the first sub-pixel further includes a plurality of static corners comprising the respective first static corner and a plurality of dynamic corners comprising the respective first dynamic corner. The plurality of static corners and the plurality of dynamic corners alternate around a perimeter of the first sub-pixel.

In an implementation of the foregoing display device, the first sub-pixel is quadrilateral or quasi-quadrilateral in shape.

In an implementation of the foregoing display device, the first and second sub-pixels are the same color.

In an implementation of the foregoing display device, the first display portion further comprises a first pixel comprising the first sub-pixel and a second pixel comprising the second sub-pixel. The centers of the first sub-pixel and the first pixel have a same relative positional relationship as the centers of the second sub-pixel and the second pixel.

In an implementation of the foregoing display device, the display device further comprises a camera arranged beneath the first display portion of the display panel and configured to capture images formed of incident light having passed through the display panel to the camera.

In an implementation of the foregoing display device, the display panel further comprises a second display portion comprising a third sub-pixel including no dynamic corners.

In an implementation of the foregoing display device, the display device further comprises an image processing system. The image processing system is configured to: receive an image captured by the camera; and utilize a machine learning (ML) model to filter a visual artifact from the image to generate a processed image.

In an implementation of the foregoing display device, the position of each first dynamic corner is randomly located.

A display panel is described herein. The display panel comprises a display portion comprising a first sub-pixel and a second sub-pixel. Each of the first and second sub-pixels includes a respective first static corner at a same position relative to a respective sub-pixel center and a respective first dynamic corner. The position of each first dynamic corner is located such that a shape of the first sub-pixel is different from the shape of the second sub-pixel.

In an implementation of the foregoing display panel, the display portion further comprises a pixel. The pixel comprises the first sub-pixel and a third sub-pixel. The third sub-pixel includes a second static corner and a second dynamic corner. The first sub-pixel is adjacent to the third sub-pixel. The position of the first dynamic corner of the first sub-pixel is located to decrease an interior angle relative to the interior angle of the first dynamic corner in a regular polygon configuration of the first sub-pixel. The position of the second dynamic corner of the third sub-pixel is located to increase an interior angle of the second dynamic corner in a regular polygon configuration of the third sub-pixel.

In an implementation of the foregoing display panel, the position of each first dynamic corner is located to decrease an interior angle relative to the interior angle of the respective first dynamic corner in a regular polygon configuration of the respective sub-pixel.

In an implementation of the foregoing display panel, each of the first and second sub-pixels further include a respective second dynamic corner. The position of each first dynamic corner and the position of each second dynamic corner are located such that respective areas of the first and second sub-pixels are within a predetermined range.

In an implementation of the foregoing display panel, the first sub-pixel further includes a plurality of static corners comprising the respective first static corner and a plurality of dynamic corners comprising the respective first dynamic corner. The plurality of static corners and the plurality of dynamic corners alternate around a perimeter of the first sub-pixel.

In an implementation of the foregoing display panel, the first sub-pixel is quadrilateral or quasi-quadrilateral in shape.

In an implementation of the foregoing display panel, the first and second sub-pixels are the same color.

In an implementation of the foregoing display panel, the display portion further comprises a first pixel comprising the first sub-pixel and a second pixel comprising the second sub-pixel. The centers of the first sub-pixel and the first pixel have a same relative positional relationship as the centers of the second sub-pixel and the second pixel.

In an implementation of the foregoing display panel, the position of each first dynamic corner is randomly located.

In an implementation of the foregoing display panel, the display panel comprises another display portion comprising a third sub-pixel. The third sub-pixel includes no dynamic corners.

A method for manufacturing a semiconductor component is described herein. The method comprises: providing a semiconductor material having a major surface, the semiconductor material comprising a first anode and a second anode; depositing organic material on the first and second anodes utilizing a first mask arranged over the semiconductor material, the first mask comprising a first sub-pixel region and a second sub-pixel region, each of the first and second sub-pixel regions respectively comprising a respective first static corner at a same position relative to a respective sub-pixel center and a respective first dynamic corner, wherein the position of each first dynamic corner is located such that a shape of the first sub-pixel region is different from the shape of the second sub-pixel region; and applying cathodes to each of the first and second sub-pixel regions of the deposited organic material.

In an implementation of the foregoing method, said depositing organic material comprises: arranging the first mask over the semiconductor material; depositing, on the first and second anodes, a first color of the organic material utilizing the first mask; arranging a second mask over the semiconductor material, the second mask comprising a third sub-pixel region; and depositing, on a third anode, a second color of the organic material utilizing the second mask.

### IX. Conclusion

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

In the discussion, unless otherwise stated, adjectives modifying a condition or relationship characteristic of a feature or features of an implementation of the disclosure, should be understood to mean that the condition or characteristic is defined to within tolerances that are acceptable for operation of the implementation for an application for which it is intended. Furthermore, if the performance of an operation is described herein as being “in response to” one or more factors, it is to be understood that the one or more factors may be regarded as a sole contributing factor for causing the operation to occur or a contributing factor along with one or more additional factors for causing the operation to occur, and that the operation may occur at any time upon or after establishment of the one or more factors. Still further, where “based on” is used to indicate an effect being a result of an indicated cause, it is to be understood that the effect is not required to only result from the indicated cause, but that any number of possible additional causes may also contribute to the effect. Thus, as used herein, the term “based on” should be understood to be equivalent to the term “based at least on.”

Numerous example embodiments have been described above. Any section/subsection headings provided herein are not intended to be limiting. Embodiments are described throughout this document, and any type of embodiment may be included under any section/subsection. Furthermore, embodiments disclosed in any section/subsection may be combined with any other embodiments described in the same section/subsection and/or a different section/subsection in any manner.

Furthermore, example embodiments have been described above with respect to one or more running examples. Such running examples describe one or more particular implementations of the example embodiments; however, embodiments described herein are not limited to these particular implementations.

Moreover, according to the described embodiments and techniques, any components of systems, user devices, display devices, display panels, cameras, display drivers, image processing systems, and/or their functions may be caused to be activated for operation/performance thereof based on other operations, functions, actions, and/or the like, including initialization, completion, and/or performance of the operations, functions, actions, and/or the like.

In some example embodiments, one or more of the operations of the flowcharts described herein may not be performed. Moreover, operations in addition to or in lieu of the operations of the flowcharts described herein may be performed. Further, in some example embodiments, one or more of the operations of the flowcharts described herein may be performed out of order, in an alternate sequence, or partially (or completely) concurrently with each other or with other operations.

The embodiments described herein and/or any further systems, sub-systems, devices and/or components disclosed herein may be implemented in hardware (e.g., hardware logic/electrical circuitry), or any combination of hardware with software (computer program code configured to be executed in one or more processors or processing devices) and/or firmware.

While various embodiments have been described above, it should be understood that they have been presented by way of example only, and not limitation. It will be apparent to persons skilled in the relevant art that various changes in form and detail can be made therein without departing from the spirit and scope of the embodiments. Thus, the breadth and scope of the embodiments should not be limited by any of the above-described example embodiments, but should be defined only in accordance with the following claims and their equivalents.

What is claimed is:

1. A display device comprising:
a display panel comprising:
a first display portion comprising a first sub-pixel and a second sub-pixel, each of the first and second sub-pixels including:
a respective first static corner at a same position relative to a respective sub-pixel center, and
a respective first dynamic corner; and
wherein the position of each first dynamic corner is located such that a shape of the first sub-pixel is different from the shape of the second sub-pixel.

2. The display device of claim 1, wherein the first display portion further comprises:
a pixel comprising:
the first sub-pixel, and
a third sub-pixel, the third sub-pixel including:
a second static corner, and
a second dynamic corner; and
wherein the first sub-pixel is adjacent to the third sub-pixel, the position of the first dynamic corner of the first sub-pixel is located to decrease an interior angle relative to the interior angle of the first dynamic corner in a regular polygon configuration of the first sub-pixel, and the position of the second dynamic corner of the third sub-pixel is located to increase an interior angle of the second dynamic corner in a regular polygon configuration of the third sub-pixel.

3. The display device of claim 1, wherein the position of each first dynamic corner is located to decrease an interior angle relative to the interior angle of the respective first dynamic corner in a regular polygon configuration of the respective sub-pixel.

4. The display device of claim 1, wherein each of the first and second sub-pixels further include:
a respective second dynamic corner; and
wherein the position of each first dynamic corner and the position of each second dynamic corner are located such that respective areas of the first and second sub-pixels are within a predetermined range.

5. The display device of claim 1, wherein the first sub-pixel further includes:
a plurality of static corners comprising the respective first static corner; and
a plurality of dynamic corners comprising the respective first dynamic corner; and
wherein the plurality of static corners and the plurality of dynamic corners alternate around a perimeter of the first sub-pixel.

6. The display device of claim 1, wherein the first sub-pixel is quadrilateral or quasi-quadrilateral in shape.

7. The display device of claim 1, wherein the first and second sub-pixels are the same color.

8. The display device of claim 1, wherein the first display portion further comprises:
a first pixel comprising the first sub-pixel; and
a second pixel comprising the second sub-pixel; and
wherein the centers of the first sub-pixel and the first pixel have a same relative positional relationship as the centers of the second sub-pixel and the second pixel.

9. The display device of claim 1, further comprising a camera arranged beneath the first display portion of the display panel and configured to capture images formed of incident light having passed through the display panel to the camera.

10. The display device of claim 9, wherein the display panel further comprises:
a second display portion comprising a third sub-pixel including no dynamic corners.

11. The display device of claim 9, further comprising an image processing system configured to:
receive an image captured by the camera; and
utilize a machine learning (ML) model to filter a visual artifact from the image to generate a processed image.

12. The display device of claim 1, wherein the position of each first dynamic corner is randomly located.

13. A display panel comprising:
a display portion comprising a first sub-pixel and a second sub-pixel, each of the first and second sub-pixels including:
a respective first static corner at a same position relative to a respective sub-pixel center, and
a respective first dynamic corner; and
wherein the position of each first dynamic corner is located such that a shape of the first sub-pixel is different from the shape of the second sub-pixel.

14. The display panel of claim 13, wherein the display portion further comprises:
a pixel comprising:
the first sub-pixel, and
a third sub-pixel, the third sub-pixel including:
a second static corner, and
a second dynamic corner; and
wherein the first sub-pixel is adjacent to the third sub-pixel, the position of the first dynamic corner of the first sub-pixel is located to decrease an interior angle relative to the interior angle of the first dynamic corner in a regular polygon configuration of the first sub-pixel, and the position of the second dynamic corner of the third sub-pixel is located to increase an interior angle of the second dynamic corner in a regular polygon configuration of the third sub-pixel.

15. The display panel of claim 13, wherein the position of each first dynamic corner is located to decrease an interior angle relative to the interior angle of the respective first dynamic corner in a regular polygon configuration of the respective sub-pixel.

16. The display panel of claim 13, wherein the first sub-pixel is quadrilateral or quasi-quadrilateral in shape.

17. The display panel of claim 13, wherein the display portion further comprises:
a first pixel comprising the first sub-pixel; and
a second pixel comprising the second sub-pixel; and
wherein the centers of the first sub-pixel and the first pixel have a same relative positional relationship as the centers of the second sub-pixel and the second pixel.

18. The display panel of claim 13, wherein the position of each first dynamic corner is randomly located.

19. A method for manufacturing a semiconductor component, comprising:
providing a semiconductor material having a major surface, the semiconductor material comprising a first anode and a second anode;
depositing organic material on the first and second anodes utilizing a first mask arranged over the semiconductor material, the first mask comprising a first sub-pixel region and a second sub-pixel region, each of the first and second sub-pixel regions respectively comprising a respective first static corner at a same position relative to a respective sub-pixel center and a respective first dynamic corner, wherein the position of each first dynamic corner is located such that a shape of the first sub-pixel region is different from the shape of the second sub-pixel region; and
applying cathodes to each of the first and second sub-pixel regions of the deposited organic material.

20. The method of claim 19, wherein said depositing organic material comprises:
arranging the first mask over the semiconductor material;
depositing, on the first and second anodes, a first color of the organic material utilizing the first mask;
arranging a second mask over the semiconductor material, the second mask comprising a third sub-pixel region; and
depositing, on a third anode, a second color of the organic material utilizing the second mask.
